(19) United States
(12) Patent Application Publication
(10) Pub. No.: US 2024/0385264 A1
(43) Pub. Date: Nov. 21, 2024

(54) MAGNETISM DETECTION DEVICE

(71) Applicant: SONY SEMICONDUCTOR SOLUTIONS CORPORATION, KANAGAWA (JP)

(72) Inventors: HIROYUKI OHMORI, KANAGAWA (JP); MASANORI HOSOMI, KANAGAWA (JP); YUTAKA HIGO, KANAGAWA (JP)

(21) Appl. No.: 18/693,032

(22) PCT Filed: Mar. 25, 2022
(86) PCT No.: PCT/JP2022/014215

§ 371 Date: Mar. 18, 2024

(30) Foreign Application Priority Data
Sep. 30, 2021 (JP) 2021-161251

(51) Int. Cl. G01R 33/09; H10N 50/10

(52) U.S. Cl. CPC G01R 33/098; G01R 33/096; H10N 50/10

(57) ABSTRACT

A decrease in detection accuracy is suppressed. A magnetism detection device according to an embodiment includes: a magnetoresistive element (10); and a detection unit (109) that detects an external magnetic field on the basis of a resistance value of the magnetoresistive element, in which the magnetoresistive element includes: a fixed layer (11) having a fixed magnetization direction; a nonmagnetic layer (12) disposed on the fixed layer; and a free layer (13) disposed on the nonmagnetic layer, the free layer having a magnetization direction varying with time, and a magnetic anisotropy axis of the free layer is parallel to the magnetization direction of the fixed layer.

### FIELD

The present disclosure relates to a magnetism detection device.

### BACKGROUND

Magnetism detection devices using principles such as the Hall effect and the magnetoresistance effect are easy to use and widely used; however, since biomagnetism associated with the brain activity, the heart and muscle activity, and the like is weak, the sensitivity of general magnetism detection means is not sufficient. Therefore, conventionally, superconducting quantum interference device (SQUID) magnetism detectors using the magnetic quantum effect are generally used for detection of biomagnetism.

Since the SQUIDs need to be cooled to a cryogenic temperature, and equipment becomes large, methods for more easily detecting biomagnetism are studied. As one method, a method of suppressing noise by parallelizing a plurality of elements having a large magnetoresistance effect has been proposed (see, for example, Patent Literature 1).

### CITATION LIST

### Patent Literature

Patent Literature 1: JP 2019-163989 A

### SUMMARY

### Technical Problem

Meanwhile, a magnetism detection device using the magnetoresistance effect basically includes a magnetization fixed layer in which magnetization is fixed and a free layer in which magnetization easily moves due to an external magnetic field and detects the magnitude of a magnetic field by electrically reading the magnetic resistance that fluctuates depending on the angle of magnetization between the magnetization fixed layer and the free layer. Therefore, finally, an analog signal such as the voltage is subjected to analog-to-digital (AD) conversion, and the magnetic field strength is read. Therefore, even if the noise of the magnetoresistive element is reduced, there is a possibility that the resolution of the magnetic field detection is limited depending on the accuracy of peripheral circuits such as an analog circuit and an AD converter, thereby deteriorating the detection accuracy.

In addition, if the anisotropic magnetic field is weakened in order to increase the sensitivity or the element size is reduced in order to increase the number of elements, it becomes susceptible to the influence of thermal fluctuation. There is also a problem that, as a result, the noise caused by the thermal fluctuation increases, thereby decreasing the detection accuracy.

Therefore, the present disclosure proposes a magnetism detection device capable of suppressing a decrease in detection accuracy.

### Solution to Problem

A magnetism detection device according to an embodiment of the present disclosure includes a magnetoresistive element; and a detection unit that detects an external magnetic field on a basis of a resistance value of the magnetoresistive element, wherein the magnetoresistive element includes: a fixed layer having a fixed magnetization direction; a nonmagnetic layer disposed on the fixed layer; and a free layer disposed on the nonmagnetic layer, the free layer having a magnetization direction varying with time, and a magnetic anisotropy axis of the free layer is parallel to the magnetization direction of the fixed layer.

### BRIEF DESCRIPTION OF DRAWINGS

FIG. 1 is a schematic diagram illustrating an exemplary schematic structure of a general magnetoresistive element.

FIG. 2 is a graph illustrating external magnetic field dependency of a resistance value of a general magnetoresistive element.

FIG. 3 is a schematic diagram illustrating an exemplary schematic structure of a magnetoresistive element according to a first embodiment.

FIG. 4 is a graph illustrating a model of temporal changes of the resistance of a magnetoresistive element in a case where no external magnetic field is applied and a case where the external magnetic field is applied according to the first embodiment.

FIG. 5 is a circuit diagram illustrating an exemplary circuit configuration of a detection circuit according to a first example of the first embodiment.

FIG. 6 is a circuit diagram illustrating an exemplary circuit configuration of a detection circuit according to a second example of the first embodiment.

FIG. 7 is a circuit diagram illustrating another exemplary circuit configuration of the detection circuit according to the second example of the first embodiment.

FIG. 8 is a circuit diagram illustrating an exemplary circuit configuration of an element assembly according to a first example of the first embodiment.

FIG. 9 is a circuit diagram illustrating an exemplary circuit configuration of an element assembly according to a second example of the first embodiment.

FIG. 10 is a circuit diagram illustrating an exemplary circuit configuration of an element assembly according to a third example of the first embodiment.

FIG. 11 is a circuit diagram illustrating an exemplary circuit configuration of a semiconductor chip according to a first example of the first embodiment.

FIG. 12 is a circuit diagram illustrating an exemplary circuit configuration of a semiconductor chip according to a second example of the first embodiment.

FIG. 13 is a circuit diagram illustrating another exemplary circuit configuration of the semiconductor chip according to the second example of the first embodiment.

FIG. 14 is a process cross-sectional view illustrating an exemplary manufacturing method of a magnetism detection device according to a first embodiment (part 1).

FIG. 15 is a process cross-sectional view illustrating the exemplary manufacturing method of the magnetism detection device according to the first embodiment (part 2).

FIG. 16 is a process cross-sectional view illustrating the exemplary manufacturing method of the magnetism detection device according to the first embodiment (part 3).

FIG. 17 is a process cross-sectional view illustrating the exemplary manufacturing method of the magnetism detection device according to the first embodiment (part 4).

FIG. 18 is a process cross-sectional view illustrating the exemplary manufacturing method of the magnetism detection device according to the first embodiment (part 5).

FIG. 19 is a process cross-sectional view illustrating the exemplary manufacturing method of the magnetism detection device according to the first embodiment (part 6).

FIG. 20 is a graph illustrating the average reversal time and the noise level of the magnetoresistive element according to the first embodiment.

FIG. 21 is a graph illustrating the noise level in a case where a plurality of magnetoresistive elements according to the first embodiment is connected in series and in parallel.

FIG. 22 is a schematic diagram illustrating an exemplary schematic structure of a magnetoresistive element according to a second embodiment.

FIG. 23 is a schematic diagram illustrating another exemplary schematic structure of the magnetoresistive element according to the second embodiment.

FIG. 24 is a diagram illustrating the relationship between the magnetization direction of a free layer in the magnetoresistive element illustrated in FIG. 22 and the direction of an external magnetic field.

FIG. 25 is a diagram illustrating the relationship between the magnetization direction of a free layer in the magnetoresistive element illustrated in FIG. 23 and the direction of an external magnetic field.

FIG. 26 is a graph illustrating an example of θ dependency of magnetic energy E when an external magnetic field H having ϕ=45 degrees according to the second embodiment is applied.

FIG. 27 is a diagram illustrating the direction of an external magnetic field with respect to a free layer according to the second embodiment.

FIG. 28 is a graph illustrating a relationship between the direction of the external magnetic field and an output signal (difference in staying times) S in a case where an in-plane magnetization film is used for the free layer according to the second embodiment.

FIG. 29 is a plan view illustrating an exemplary schematic structure of the magnetoresistive element according to the second embodiment.

FIG. 30 is a plan view illustrating an exemplary schematic structure of another magnetoresistive element according to the second embodiment.

FIG. 31 is a plan view illustrating an exemplary schematic structure of still another magnetoresistive element according to the second embodiment.

FIG. 32 is a plan view illustrating an exemplary schematic structure of yet another magnetoresistive element according to the second embodiment.

FIG. 33 is a plan view illustrating an exemplary schematic structure of still yet another magnetoresistive element according to the second embodiment.

FIG. 34 is a plan layout view illustrating an array example of magnetoresistive elements that detect an external magnetic field in two axes (X axis and Y axis) in a plane, the magnetoresistive elements according to a first example of the second embodiment.

FIG. 35 is a plan layout view illustrating an array example of magnetoresistive elements that detect an external magnetic field in two axes (X axis and Y axis) in a plane, the magnetoresistive elements according to a second example of the second embodiment.

FIG. 36 is a plan layout view illustrating an array example of magnetoresistive elements that detect an external magnetic field in three axes (X axis, Y axis, and X axis), the magnetoresistive elements according to a third example of the second embodiment.

FIG. 37 is a plan layout view illustrating an array example of magnetoresistive elements that detect an external magnetic field in three axes (X axis, Y axis, and X axis), the magnetoresistive elements according to a fourth example of the second embodiment.

FIG. 38 is a process cross-sectional view illustrating an exemplary manufacturing method of a magnetism detection device according to a second embodiment (part 1).

FIG. 39 is a process cross-sectional view illustrating the exemplary manufacturing method of the magnetism detection device according to the second embodiment (part 2).

FIG. 40 is a process cross-sectional view illustrating the exemplary manufacturing method of the magnetism detection device according to the second embodiment (part 3).

FIG. 41 is a process cross-sectional view illustrating the exemplary manufacturing method of the magnetism detection device according to the second embodiment (part 4).

FIG. 42 is a process cross-sectional view illustrating the exemplary manufacturing method of the magnetism detection device according to the second embodiment (part 5).

FIG. 43 is a process cross-sectional view illustrating the exemplary manufacturing method of the magnetism detection device according to the second embodiment (part 6).

FIG. 44 is a process cross-sectional view illustrating the exemplary manufacturing method of the magnetism detection device according to the second embodiment (part 7).

FIG. 45 is a process cross-sectional view illustrating the exemplary manufacturing method of the magnetism detection device according to the second embodiment (part 8).

FIG. 46 is a process cross-sectional view illustrating the exemplary manufacturing method of the magnetism detection device according to the second embodiment (part 9).

FIG. 47 is a process cross-sectional view illustrating another exemplary manufacturing method of the magnetism detection device according to the second embodiment (part 1).

FIG. 48 is a process cross-sectional view illustrating the other exemplary manufacturing method of the magnetism detection device according to the second embodiment (part 2).

FIG. 49 is a process cross-sectional view illustrating the other exemplary manufacturing method of the magnetism detection device according to the second embodiment (part 3).

FIG. 50 is a process cross-sectional view illustrating the other exemplary manufacturing method of the magnetism detection device according to the second embodiment (part 4).

FIG. 51 is a process cross-sectional view illustrating the other exemplary manufacturing method of the magnetism detection device according to the second embodiment (part 5).

FIG. 52 is a process cross-sectional view illustrating the other exemplary manufacturing method of the magnetism detection device according to the second embodiment (part 6).

FIG. 53 is a process cross-sectional view illustrating the other exemplary manufacturing method of the magnetism detection device according to the second embodiment (part 7).

FIG. 54 is a block diagram illustrating an exemplary schematic configuration of a magnetism detection device according to a third embodiment.

### DESCRIPTION OF EMBODIMENTS

Hereinafter, embodiments of the present disclosure will be described in detail on the basis of the drawings. Note that in each of the following embodiments, the same parts are denoted by the same symbols, and redundant description will be omitted.

The present disclosure will be described in the following order of items.
1. First Embodiment
1.1 About Magnetoresistive Element
1.2 Example of Detection Circuit
1.2.1 First Example
1.2.2 Second Example
1.3 Configuration Example of Element Assembly
1.3.1 First Example
1.3.2 Second Example
1.3.3 Third Example
1.4 Configuration Example of Semiconductor Chip
1.4.1 First Example
1.4.2 Second Example
1.5 Manufacturing Method
1.6 Action and Effects
2. Second Embodiment
2.1 Configuration Example of Magnetoresistive Element
2.2 Variations of Magnetoresistive Element
2.3 Array Example of Magnetoresistive Elements
2.3.1 First Example
2.3.2 Second Example
2.3.3 Third Example
2.3.4 Fourth Example
2.4 Exemplary Manufacturing Method
2.4.1 Modification of Manufacturing Method
2.5 Action and Effects
3. Third Embodiment

### 1. FIRST EMBODIMENT

Hereinafter, a magnetoresistive element and a magnetism detection device according to a first embodiment of the present disclosure will be described in detail with reference to the drawings.

1.1 about Magnetoresistive Element

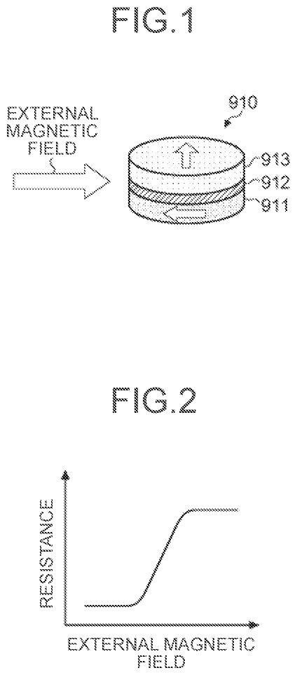

In the present embodiment, first, a magnetoresistive element will be described. FIG. 1 is a schematic diagram illustrating an exemplary schematic structure of a general magnetoresistive element. As illustrated in FIG. 1, a magnetoresistive element 910 includes a magnetization fixed layer (hereinafter, also simply referred to as a fixed layer) 911 whose magnetization direction is fixed, a free layer 913 whose magnetization direction changes depending on an external magnetic field, and a nonmagnetic layer 912 disposed between the fixed layer 911 and the free layer 3.

In a state where there is no external magnetic field, with arrangement in which the angle between the magnetization direction of the fixed layer 911 and the magnetization direction of the free layer 913 is approximately 90 degrees, the linearity of a response to the external magnetic field or the detectable area of a magnetic field can be improved.

The magnetization direction of the fixed layer 911 is fixed by bonding a ferromagnetic material such as a cobalt-iron (CoFe) alloy to an antiferromagnetic material such as a manganese platinum (PtMn) alloy or an iridium-manganese (IrMn) alloy.

The fixed layer 911 has a structure in which two ferromagnetic layers are laminated with an extremely thin ruthenium (Ru) layer, an iridium (Ir) layer, or the like. As a result, since the ferromagnetic layers are coupled in antiparallel, a stray magnetic field from the fixed layer 911 can be reduced.

For the free layer 913, a magnetic material having weak magnetic anisotropy such as a CoFe alloy, a nickel-iron (NiFe) alloy, or a cobalt-iron boron (CoFeB) alloy is used so as to easily fluctuate with respect to an external magnetic field. As the nonmagnetic layer, there are cases of using a good conductor such as copper (Cu) and cases of using an insulator such as alumina (Al₂O₃) or magnesium oxide (MgO). A large resistance change can be obtained by, in a case where a good conductor is used, causing a current to flow on the film surface to utilize the giant magnetoresistive (GMR) effect and in a case where an insulator is used, causing a current to flow in a direction perpendicular to the film surface to utilize the tunnel magnetoresistance (TMR) effect.

In FIG. 2, external magnetic field dependency of a resistance value of a general magnetoresistive element described above is illustrated. As illustrated in FIG. 2, when the external magnetic field is weak, the resistance tends to change substantially linearly with respect to the external magnetic field and be saturated when the external magnetic field increases to some extent or more. Increasing the inclination angle in order to increase the sensitivity to the external magnetic field makes it easier to cause saturation, thereby reducing the maximum magnetic field that can be detected.

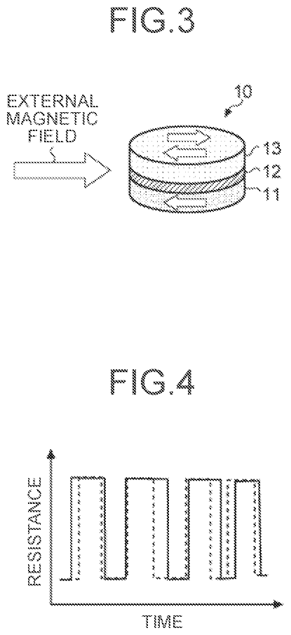

Next, an overview of a magnetoresistive element according to the present embodiment will be described with reference to FIG. 3. FIG. 3 is a schematic diagram illustrating an exemplary schematic structure of the magnetoresistive element according to the present embodiment.

As illustrated in FIG. 3, the layer structure, lamination form, and the like of a magnetoresistive element 10 according to the present embodiment are similar to those of the general magnetoresistive element 910 illustrated in FIG. 1 as an example; however, it is characteristic that the magnetic anisotropy of a free layer 13 is made parallel to the magnetization direction of a fixed layer 11.

In a case where the magnetic anisotropy axis of the free layer 13 is made parallel to the magnetization direction of the fixed layer 11, the magnetization direction of the free layer 13 is limited to either parallel or antiparallel to the magnetization direction of the fixed layer 11 depending on the direction of the external magnetic field or the magnitude of the magnetic field. That is, the resistance of the magnetoresistive element 10 roughly has two values of high resistance and low resistance.

However, in a case where the volume of the free layer 13 is large, the magnetization direction is stable by being either parallel or antiparallel, whereas in a case where the volume of the free layer 13 is reduced, the effect of thermal fluctuation causes transition between the parallel state and the antiparallel state.

Here, an index Δ₀ of the thermal stability is expressed by the following Equation (1) using the magnetic anisotropy energy Ku, the volume V of the magnetic material, the temperature T, and the Boltzmann constant KB.

$${Δ}_{0} = K u V / k B T \qquad ( 1 )$$

Therefore, the reversal probability P that the magnetization direction of the free layer 13 is reversed during time t can be expressed as the following Equation (2). In Equation (2), τ₀ is a relaxation constant.

$$P = 1 - exp \{ - t / {τ}_{0} \cdot exp ( - {Δ}_{0} ) \qquad ( 2 )$$

In a case where an external magnetic field is applied to the magnetoresistive element 10, Δp in a state parallel to the applied magnetic field and Δap in an antiparallel state are expressed by the following Equations (3) and (4), respectively. In Equations (3) and (4), Hk is the magnitude of the anisotropic magnetic field.

$$Δ p = {Δ}_{0} \cdot {( 1 + H / Hk )}^{2} \qquad ( 3 )$$

$$Δ ap = {Δ}_{0} \cdot {( 1 - H / Hk )}^{2} \qquad ( 4 )$$

As illustrated in Equations (3) and (4), when the external magnetic field is applied to the magnetoresistive element 10, a difference is generated between Δp and Δap, and a difference is generated between the reversal probability from the parallel state to the antiparallel state and the reversal probability from the antiparallel state to the parallel state. That is, a difference is generated between staying time in the parallel state and staying time in the antiparallel state. Illustrated in FIG. 4 is a model of temporal changes of the resistance of the magnetoresistive element 10 in a case where no external magnetic field is applied and a case where the external magnetic field is applied. Note that, in FIG. 4, a broken line indicates a temporal change of the resistance in the case where no external magnetic field is applied, and a solid line indicates a temporal change of the resistance in the case where the external magnetic field is applied.

However, since the reversal of the magnetization direction in the free layer 13 occurs stochastically, there is large fluctuation in the time difference between the staying times of the states. In order to reduce this fluctuation, it is effective to increase the number of times of reversals per observation time, namely, to reduce Δ, and it is preferable to maintain the average reversal time to less than or equal to 10 milliseconds. The shorter the reversal time is, the smaller the fluctuation becomes; however, if the reversal time is shorter than 0.1 microseconds, the spin torque noise due to a read current increases.

The magnetic anisotropy Hk is an important parameter that determines the sensitivity of the magnetoresistive element. If the magnetic anisotropy Hk is too large, the sensitivity decreases, and if the magnetic anisotropy Hk is too small, the magnetization direction becomes unstable. Therefore, it is preferable that the magnetic anisotropy Hk have an appropriate magnitude. The magnetic anisotropy Hk can be controlled by imparting induced magnetic anisotropy by performing film formation or heat treatment in a magnetic field or imparting shape anisotropy by shaping into an asymmetric shape such as an elliptical shape.

Furthermore, in order to reduce the influence of fluctuation, it is sufficient to increase the number of elements to average the states. For example, by arranging elements in series or in parallel and measuring information of a difference between the number of elements in the high resistance state and the number of elements in the low resistance state as a resistance value as an assembly, the influence of the fluctuation can be reduced. In addition, the influence of fluctuation can also be reduced by temporally using a resistance value as an electric signal and by performing integration or allowing to pass through a low-pass filter circuit that removes high-frequency components.

In the case of structuring the assembly of elements, a plurality of elements may be connected in series or connected in parallel, or direct connection and parallel connection may be combined. At that point, in a case where a good conductor is used for the nonmagnetic layer of the element, a resistance value that is easier to read is obtained from serial connection, and in a case where an insulator is used, a resistance value that is easier to read is obtained from parallel connection.

### 1.2 Example of Detection Circuit

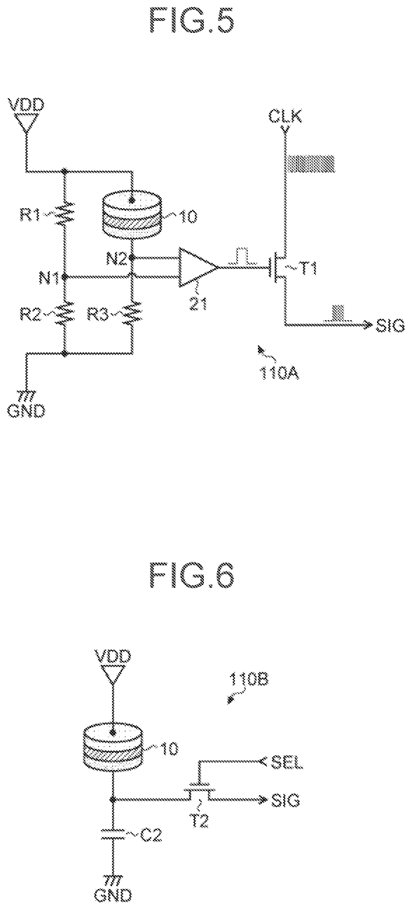

Next, a circuit configuration example for reading a difference in reversal probabilities for each magnetoresistive element will be described with reference to FIGS. 5 to 7. Incidentally, although a case where a magnetic tunnel junction (MTJ) element having a large resistance value is used as the magnetoresistive element 10 is illustrated in FIGS. 5 to 7, it is not limited thereto, and various magnetoresistive elements may be used.

### 1.2.1 First Example

FIG. 5 is a circuit diagram illustrating a circuit configuration example of a detection circuit according to a first example of the embodiment and is a circuit diagram illustrating an example of a detection circuit for acquiring a difference in reversal probabilities by measuring time during which the magnetoresistive element is in a parallel state and time during which the magnetoresistive element is in an antiparallel state, that is, time in a high resistance state and time in a low resistance state.

A detection circuit 110A illustrated in FIG. 5 includes the magnetoresistive element 10, three resistors R1 to R3, a comparator 21, and a CMOS transistor T1. The comparator 21 uses the potential of a connection node N1 of the two resistors R1 and R2 connected in series between a power supply voltage VDD and a ground potential GND as a reference potential, compares the reference potential with the potential of a connection node N2 of the magnetoresistive element 10 and the resistor R3 also connected in series between the power supply voltage VDD and the ground potential GND, and applies the result to a gate of the CMOS transistor T1. That is, the CMOS transistor T1 functions as a gate circuit that opens and closes depending on the resistance value (in other words, the magnetization direction of the free layer 13) of the magnetoresistive element 10.

For example, in a case where the potential of the connection node N2 is higher than the potential of the connection node N1, namely, in the case where the magnetoresistive element 10 is in the parallel state (low resistance state), a comparison result of level High output from the comparator 21 is applied to the gate of the CMOS transistor T1. Accordingly, since the CMOS transistor T1 is brought into a conductive state (also referred to as an open state), a pulse signal indicating information related to staying time (also referred to as first staying time) during which a state, in which the magnetization direction of the free layer 13 is parallel to the magnetization direction of the fixed layer 11, is maintained is output as an output signal SIG from the detection circuit 110A. Note that the pulse signal may be a signal that transitions between level High and level Low at a predetermined cycle and may be, for example, a clock signal CLK or the like.

On the other hand, in a case where the potential of the connection node N2 is lower than the potential of the connection node N1, namely, in the case where the magnetoresistive element 10 is in the antiparallel state (high resistance state), a comparison result of level Low output from the comparator 21 is applied to the gate of the CMOS transistor T1. This brings the CMOS transistor T1 into a blocked state (also referred to as a closed state), and thus the output of the clock signal CLK from the detection circuit 110A is blocked. That is, the period during which the output of the clock signal CLK is blocked indicates information related to staying time (also referred to as second staying time) during which a state, in which the magnetization direction of the free layer 13 is antiparallel to the magnetization direction of the fixed layer 11, is maintained.

Therefore, in the case of using the detection circuit 110A illustrated in FIG. 5, by counting the number of pulses of the clock signal CLK output as the output signal SIG from the detection circuit 110A during a measurement period, measuring a period in which the magnetoresistive element 10 is in the parallel state (also referred to as a parallel state period), calculating a period in which the magnetoresistive element 10 is in the antiparallel state (also referred to as an antiparallel state period) from the parallel state period and the measurement period, and calculating the difference between the parallel state period and the antiparallel state period, it is possible to acquire the difference in reversal probabilities.

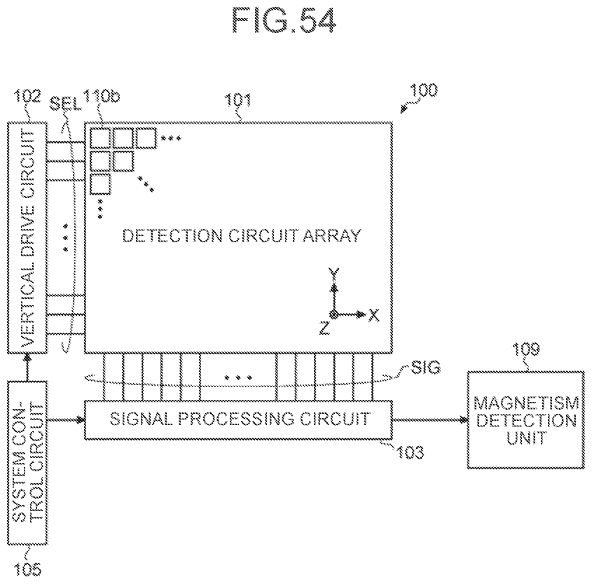

Note that, in a case where a magnetism detection device includes a plurality of detection circuits 110A, a magnetism detection unit (see, for example, a magnetism detection unit 109 in FIG. 54) that detects an external magnetic field on the basis of a resistance value of a magnetoresistive element may calculate a difference between the parallel state period and the antiparallel state period by integrating count values obtained by counting digital output signals SIG output from the detection circuits 110A, thereby acquiring a difference in reversal probabilities.

### 1.2.2 Second Example

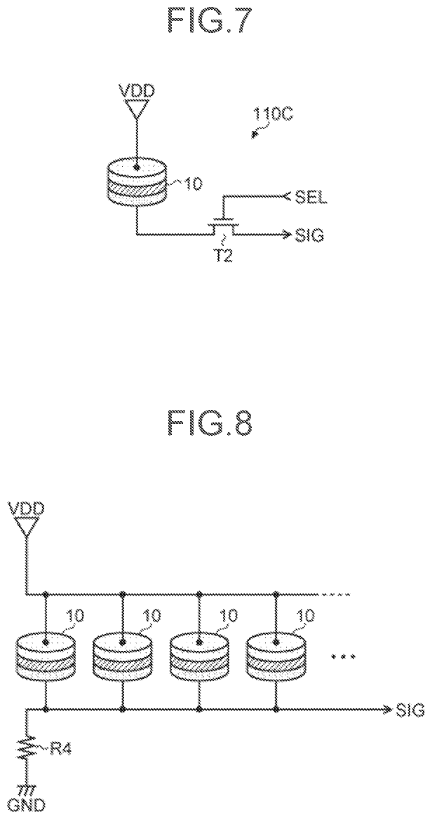

FIGS. 6 and 7 are circuit diagrams illustrating circuit configuration examples of a detection circuit according to a second example of the embodiment and are circuit diagrams illustrating examples of a detection circuit for acquiring a difference in reversal probabilities on the basis of the amount of charges flowing through the magnetoresistive element during a measurement period.

A detection circuit 110B illustrated in FIG. 6 includes the magnetoresistive element 10, a capacitor C2, and a CMOS transistor T2. The capacitor C2 accumulates charges having flowed through the magnetoresistive element 10 during the measurement period. Therefore, the amount of charges accumulated in the capacitor C2 indicates the information regarding the first staying time during which the state in which the magnetization direction of the free layer 13 is parallel to the magnetization direction of the fixed layer 11 is maintained.

The charges accumulated in the capacitor C2 are output as an output signal SIG via the CMOS transistor T2 brought into a conductive state by a selection signal SEL.

Therefore, in the case of using the detection circuit 110B illustrated in FIG. 6, it is possible to acquire the difference in reversal probabilities by calculating the difference between the amount of charges output as the output signal SIG from the detection circuit 110B and the amount of charges accumulated in the capacitor C2, for example, in a case where the magnetoresistive element 10 is always kept in the low resistance state during the measurement period.

Meanwhile, a detection circuit 110C illustrated in FIG. 7 is configured to read the charges accumulated in the magnetoresistive element 10, instead of the capacitor C2, as an output signal SIG in a similar configuration to that of the detection circuit 110B illustrated in FIG. 6. In this case, the amount of charges accumulated in the magnetoresistive element 10 indicates the information regarding the first staying time during which the state in which the magnetization direction of the free layer 13 is parallel to the magnetization direction of the fixed layer 11 is maintained.

Also with such a configuration, it is possible to acquire the difference in reversal probabilities by calculating the difference between the amount of charges output as the output signal SIG from the detection circuit 110C and, for example, the amount of charges accumulated in the magnetoresistive element 10 in a case where the magnetoresistive element 10 is always kept in the low resistance state during the measurement period.

Note that, in a case where a magnetism detection device includes a plurality of detection circuits 110B or 110C, the magnetism detection unit may acquire the difference in reversal probabilities by accumulating charges read as the output signal SIG from the detection circuits 110B or 110C and calculating a difference from the total amount of charges accumulated when all the magnetoresistive elements 10 are always kept in the low resistance state during the measurement period.

### 1.3 Configuration Example of Element Assembly

Next, a configuration example of an element assembly in a case where information of a difference between the number of elements in the high resistance state and the number of elements in the low resistance state is measured as a resistance value as the assembly will be described with reference to FIGS. 8 to 10.

### 1.3.1 First Example

FIG. 8 is a circuit diagram illustrating a circuit configuration example of an element assembly according to a first example of the embodiment and is a circuit diagram illustrating the circuit configuration example of the element assembly in a case where a plurality of magnetoresistive elements is connected in parallel. As illustrated in FIG. 8, the element assembly may have a configuration in which a plurality of magnetoresistive elements 10 is connected in parallel between a power supply voltage VDD and a resistor R4. In this case, the potentials of connection nodes connecting the plurality of magnetoresistive elements 10 and the resistor R4 may be read out as an output signal SIG.

### 1.3.2 Second Example

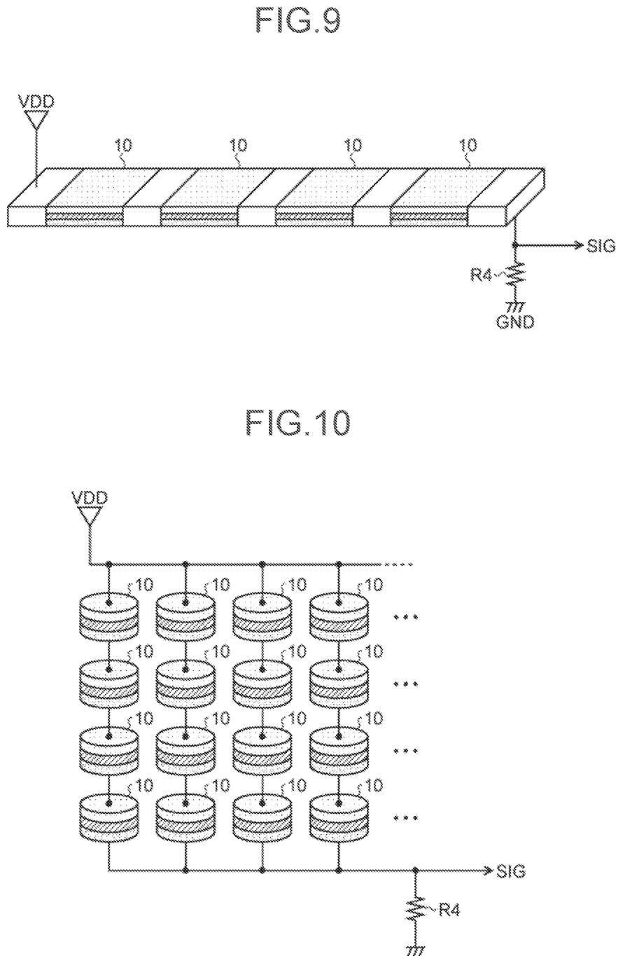

FIG. 9 is a circuit diagram illustrating a circuit configuration example of an element assembly according to a second example of the embodiment and is a circuit diagram illustrating the circuit configuration example of the element assembly in a case where a plurality of magnetoresistive elements is connected in series. As illustrated in FIG. 9, the element assembly may have a configuration in which a plurality of magnetoresistive elements 10 is connected in series between a power supply voltage VDD and a resistor R4. In this case, the potential of a connection node connecting the plurality of magnetoresistive elements 10 connected in series and the resistor R4 may be read out as an output signal SIG.

### 1.3.3 Third Example

FIG. 10 is a circuit diagram illustrating a circuit configuration example of an element assembly according to a third example of the embodiment and is a circuit diagram illustrating the circuit configuration example of the element assembly in a case where a plurality of magnetoresistive elements is connected in series. As illustrated in FIG. 10, the element assembly may have a configuration in which a plurality of element strings, each including a plurality of magnetoresistive elements 10 connected in series, is connected in parallel between a power supply voltage VDD and a resistor R4. In this case, the potentials of connection nodes connecting the plurality of element strings connected in parallel and the resistor R4 may be read out as an output signal SIG. 1.4 Configuration Example of Semiconductor Chip

Next, circuit examples will be described with some examples in a case where the magnetoresistive element(s) 10 is/are integrated on a semiconductor chip alone or as an assembly.

### 1.4.1 First Example

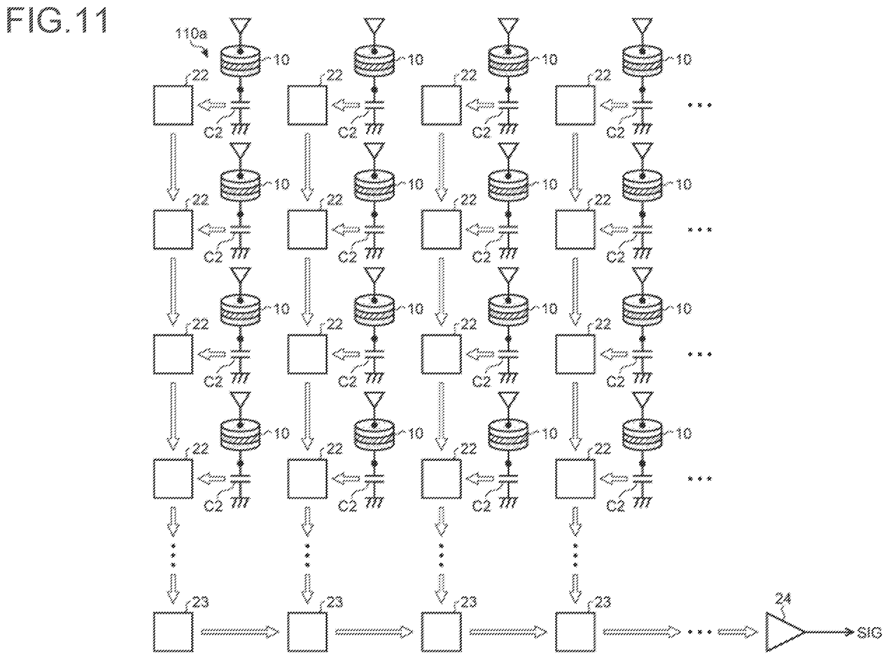

FIG. 11 is a circuit diagram illustrating a circuit configuration example of a semiconductor chip according to a first example of the embodiment and is a diagram illustrating an example of a case where the charge of a capacitor connected to a magnetoresistive element is transferred by a charge coupled device (CCD) and read out.

As illustrated in FIG. 11, in the first example, a plurality of detection circuits 110a is integrated on the semiconductor chip in a state of being arrayed in a two-dimensional lattice pattern. For example, similarly to the second example of the detection circuit illustrated in FIG. 6, each of the detection circuits 110a has a configuration in which a magnetoresistive element 10 and a capacitor C2 are connected in series between a power supply voltage VDD and a ground potential GND and is configured in such a manner that the charges having flowed through the magnetoresistive element 10 during a measurement period are accumulated in the capacitor C.

The charges accumulated in the capacitors C2 of the respective detection circuits 110a flow into a charge-voltage conversion circuit 24 via a plurality of vertical transfer CCDs 22 arranged in parallel to respective columns and a plurality of horizontal transfer CCDs 23 arranged for respective rows, are converted into a voltage signal, which is output as an output signal SIG. That is, the charges accumulated in the capacitors C2 of the respective detection circuits 110a are sequentially transferred and aggregated by the CCDs 22 and 23 and flow into the charge-voltage conversion circuit 24. Then, the charges are converted into a voltage signal in the charge-voltage conversion circuit 24 and output as the output signal SIG.

Note that, although a magnetoresistive element 10 and a capacitor C1 are directly connected in FIG. 11, a CMOS switch may be disposed between the magnetoresistive element 10 and the capacitor C1 in order to suppress leakage of charges from the capacitor C1.

### 1.4.2 Second Example

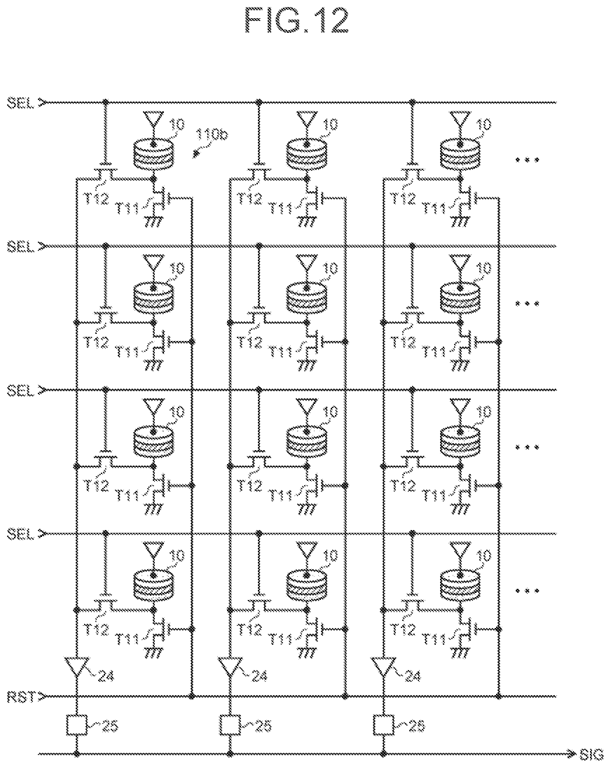

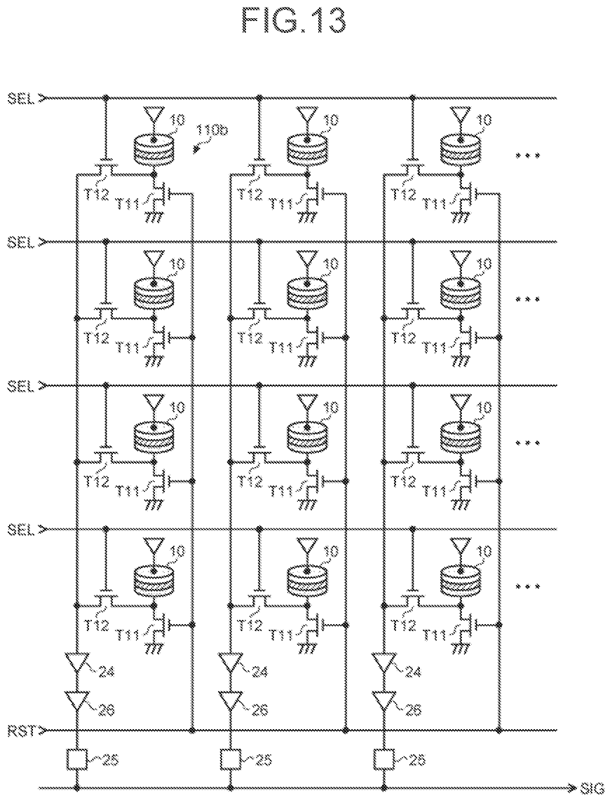

FIGS. 12 and 13 are circuit diagrams illustrating circuit configuration examples of a semiconductor chip according to a second example of the embodiment and are diagrams illustrating examples of a case where charges are read from detection circuits of a selected row in each of columns.

In the example illustrated in FIG. 12, similarly to the first example, a plurality of detection circuits 110b is integrated on the semiconductor chip in a state of being arrayed in a two-dimensional lattice pattern. Each of the detection circuits 110b has, for example, a configuration in which a magnetoresistive element 10 and a CMOS transistor T11 are connected in series between a power supply voltage VDD and a ground potential GND, and a CMOS transistor T12 as a selection transistor is connected to a connection node between the magnetoresistive element 10 and the CMOS transistor T11. Note that, in the second example, similarly to the second example of the detection circuit illustrated in FIG. 7, the magnetoresistive elements 10 themselves are used to accumulate charges.

In this example, when a reset signal RST is applied to a reset line at the start of operation, a voltage is applied to both terminals of a magnetoresistive element 10, and charges are accumulated in the magnetoresistive element 10. Here, as described above, the magnetoresistive element 10 functions as a resistive element. Therefore, the charges accumulated in the magnetoresistive element 10 decreases depending on the magnetization direction of the free layer 13. Therefore, a selection signal SEL is applied to a selection line when a certain period of time has elapsed from the application of the reset signal RST. Then, the charges remaining in the magnetoresistive element 10 flows into the charge-voltage conversion circuit 24 via a signal line, is converted into a voltage signal, is further converted into a digital signal by an analog-to-digital (AD) conversion circuit 25, and is output as an output signal SIG. Note that the rows (selected rows) simultaneously selected by the selection signal SEL may be one row or a plurality of rows (including all rows).

Furthermore, in the example illustrated in FIG. 13, a low-pass filter 26 is disposed between a charge-voltage conversion circuit 24 and an AD conversion circuit 25 in a configuration similar to the example illustrated in FIG. 12. The low-pass filter 26 integrates analog signals before the AD conversion or removes high-frequency components of the analog signal. This makes it possible to remove the influence of the high-frequency components, thereby making it possible to suppress a decrease in the detection accuracy due to noise or the like. Note that the position of the low-pass filter 26 is not limited to that between the charge-voltage conversion circuit 24 and the AD conversion circuit 25 and may be variously modified as long as it is between the magnetoresistive element 10 and the AD conversion circuit 25.

In the above, the case of reading out the charges accumulated in the capacitors C2 or the magnetoresistive elements 10 has been described as an example; however, it is not limited thereto. For example, a resistance value of a magnetoresistive element 10 may be directly measured by supplying a constant current to the magnetoresistive element 10 and reading out a potential difference generated at both ends of the magnetoresistive element 10.

In addition, in the first example and the second example, the cases where each of the detection circuits 110a and 110b includes one magnetoresistive element 10 are described as the examples; however, it is not limited thereto. For example, as exemplified in FIGS. 8 to 10, one detection circuit may include a plurality of magnetoresistive elements 10 connected in series and/or in parallel.

Furthermore, in a case where each of the configurations illustrated in FIGS. 11 to 13 is regarded as one block, one block or a plurality of blocks may be arranged in one semiconductor chip. Furthermore, the semiconductor chip may have a single-layer structure in which a plurality of blocks is arranged in one semiconductor layer or may have a laminated structure in which a plurality of semiconductor chips, in which one or a plurality of blocks is arranged in one semiconductor layer, is laminated.

### 1.5 Manufacturing Method

Next, an example of a manufacturing method of the magnetism detection device according to the present embodiment will be described. FIGS. 14 to 19 are process cross-sectional views illustrating an exemplary manufacturing method of the magnetism detection device according to the embodiment. Note that, in the following description, attention is paid to some basic units of the magnetism detection device to facilitate understanding.

In the present manufacturing method, first, peripheral circuits such as the charge-voltage conversion circuit 24 and the AD conversion circuit 25 are formed on a semiconductor substrate such as a silicon substrate. Next, a lower electrode connected to the peripheral circuits is formed on a part of the semiconductor substrate in which the peripheral circuits are formed. As a result, a base substrate 40 including the peripheral circuits is manufactured. Note that an element formation surface (hereinafter, also referred to as an upper surface) of the semiconductor substrate on which the lower electrode is formed may be embedded by an insulating layer except for a connection portion with a magnetoresistive element 10 to be formed later.

Next, as illustrated in FIG. 14, a laminated film 50, in which a first layer 51 to be processed into a fixed layer 11, a second layer 52 to be processed into a nonmagnetic layer 12, and a third layer 53 to be processed into a free layer 13 are laminated in the order mentioned, is formed on the entire surface of the base substrate 40. Note that, for deposition of the first layer 51 to the third layer 53, various types of deposition technology depending on each of the layers, such as a chemical vapor deposition (CVD) method or a sputtering method, may be used.

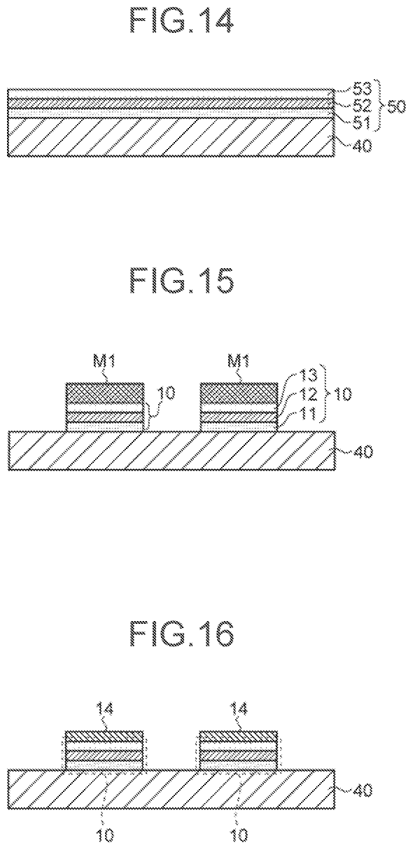

Next, as illustrated in FIG. 15, for example, photolithography or the like is used to form a mask M1 on the laminated film 50, and the laminated film 50 exposed from the mask M1 is dug using etching technology such as reactive ion etching (RIE) to form magnetoresistive elements 10 of a mesa shape.

Note that the magnetoresistive elements 10 may have a configuration in which the fixed layer 11 to the free layer 13 are patterned in a columnar or elliptical columnar shape; however, for example, only the free layer 13 may be patterned and the layers under the nonmagnetic layer 12 may be left as they are with a large area. As a result, a short circuit of the nonmagnetic layer 12 can be suppressed, and a stray magnetic field from the fixed layer 11 can also be reduced. Furthermore, in the present example, the case where the plurality of magnetoresistive elements 10 is arrayed in a two-dimensional lattice pattern on the element formation surface of the base substrate 40 is described as an example; however, the number of the magnetoresistive elements 10 formed on the base substrate 40 may be one or plural. Furthermore, in the present example, a case where all the magnetoresistive elements 10 are arrayed in one layer is described as an example; however, it is not limited thereto, and a plurality of magnetoresistive elements 10 may be dispersedly arranged in a plurality of layers.

Next, as illustrated in FIG. 16, for example, upper electrodes 14 are formed on the upper surfaces of the magnetoresistive elements 10 by using the lift-off technology or the like.

Next, as illustrated in FIG. 17, an insulating layer 41 is formed in such a manner as to embed structures 15 each including a magnetoresistive element 10 and an upper electrode 14 by using, for example, the CVD method or the sputtering method. Note that, an upper surface of the insulating layer 41 may be leveled by, for example, chemical mechanical polishing (CMP).

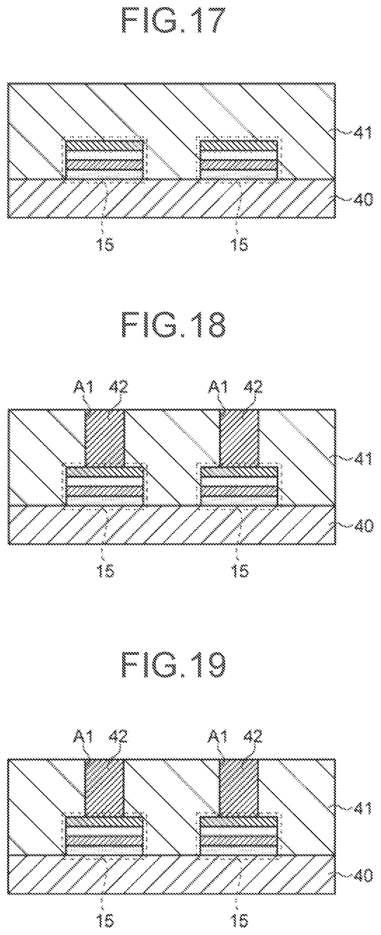

Next, as illustrated in FIG. 18, openings A1 for exposing parts of the upper surfaces of the upper electrodes 14 are formed in the insulating layer 41 by using, for example, the photolithography technology and the etching technology.

Next, as illustrated in FIG. 19, pieces of wiring 42 connected to the upper electrodes 14 are embedded in the openings A1 of the insulating layer 41. Thereafter, a wire connecting the pieces of wiring 42 to a power supply voltage VDD is formed on the insulating layer 41, thereby manufacturing the magnetism detection device according to the present embodiment. Note that, in a case where a plurality of magnetism detection devices is collectively built in one wafer, a step of singulating and packaging the wafer into semiconductor chips may be executed. In addition, in a case where the magnetism detection device (block) has a configuration in which a plurality of semiconductor chips is stacked, a step of bonding the semiconductor chips may be executed.

### 1.6 Action and Effects

As described above, by acquiring the reversal probabilities of the magnetization direction of the free layers 13 on the basis of detection results from the plurality of magnetoresistive elements 10 in which the volumes of the respective free layers 13 are reduced, it is possible to reduce the influence of the fluctuation in the duration of each of the parallel state and the antiparallel state by a statistical method, and thus, it is possible to suppress a decrease in the detection accuracy of the external magnetic field.

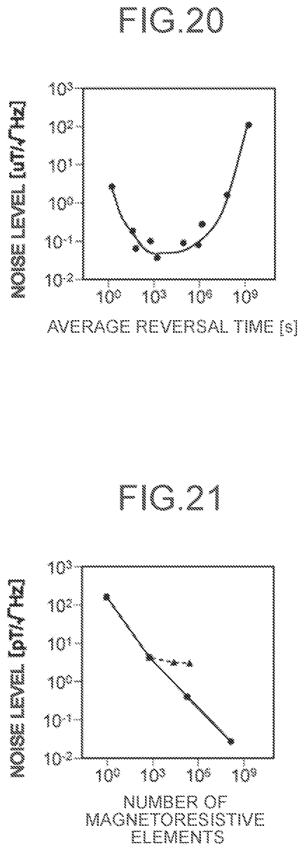

FIG. 20 is a graph illustrating the average reversal time and the noise level of the magnetoresistive element according to the embodiment. Note that, in the example illustrated in FIG. 20, a film having an MTJ structure was used in which tantalum (Ta) having a thickness of 5 nanometers (nm), a platinum manganese (PtMn) alloy having a thickness of 10 nm, a cobalt-iron (CoFe) alloy having a thickness of 2 nm, ruthenium (Ru) having a thickness of 0.8 nm, tungsten (W) having a thickness of 0.1 nm, a cobalt-iron boron (CoFeB) alloy having a thickness of 2.5 nm, magnesium oxide (MgO) having a thickness t, a CoFeB alloy having a thickness of 3 nm, and tantalum (Ta) having a thickness of 5 nm are laminated in the order mentioned. Note that the thickness t of MgO was adjusted in such a manner that the magnetoresistive element 10 has a targeted resistance value. In addition, the magnitude of the magnetic anisotropy and the volume of the free layer 13 were varied by varying the size and the aspect ratio of the element, and the voltage applied to the magnetoresistive element 10 was set to 0.1 volt (V). Then, the average reversal time was set to an interval crossing an intermediate value between the high resistance and the low resistance, and a signal having passed through a low-pass filter having a time constant of 0.1 seconds was measured as the noise level. In this case, as illustrated in FIG. 20, it can be seen that the noise level exhibits a low value when the average reversal time is between 0.1 microseconds and 10 milliseconds.

FIG. 21 is a graph illustrating the noise level in a case where a plurality of magnetoresistive elements 10 is connected in series and in parallel. Note that, in FIG. 21, the thickness t of MgO of the magnetoresistive elements 10 was increased to increase the resistance of the individual elements, the number of the magnetoresistive elements 10 connected in parallel was set to 1024, and units, each including 1024 magnetoresistive elements 10 connected in parallel, were connected in parallel and in series. In addition, in FIG. 21, a broken line indicates the noise level in a case where the output from a plurality of units as a whole is AD-converted, and a solid line indicates a noise level in a case where pieces of output from the individual units are AD-converted and then added. As illustrated in FIG. 21, it can be seen that in a case where the output from the plurality of units as a whole is AD-converted, reduction of the noise level is limited due to electrical noise or resolution of the AD conversion circuit; however, in a case where the pieces of output from the individual units are AD-converted and then added, the noise level is reduced as the number of units is increased.

### 2. SECOND EMBODIMENT

Next, a magnetoresistive element and a magnetism detection device according to a second embodiment of the present disclosure will be described in detail with reference to the drawings. Note that, in the following description, redundant description for similar structure, operation, manufacturing method, and effects to those of the above-described embodiment are omitted by citing those of the embodiment.

As described in the first embodiment, in a case where the magnetic anisotropy axis of the free layer 13 is made parallel to the magnetization direction of the fixed layer 11, the magnetization direction of the free layer 13 can be limited to either parallel or antiparallel to the magnetization direction of the fixed layer 11 depending on the direction of the external magnetic field or the magnitude of the magnetic field. Therefore, in the present embodiment, description will be given, with an example, on a magnetism detection device capable of detecting not only the magnitude of an external magnetic field but also the direction of the external magnetic field by utilizing such properties.

### 2.1 Configuration Example of Magnetoresistive Element

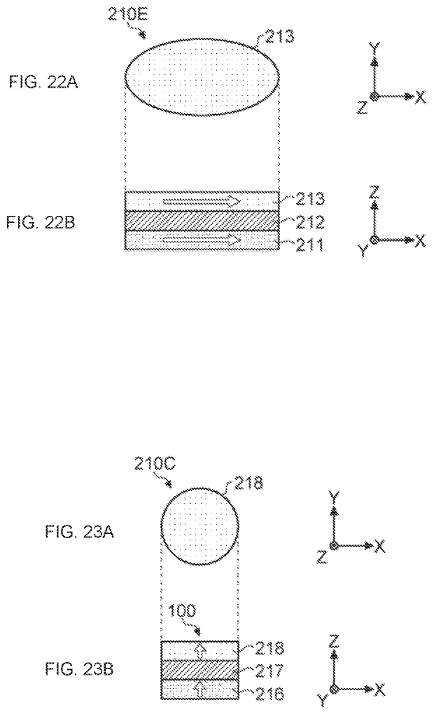

FIGS. 22 and 23 are schematic diagrams illustrating exemplary schematic structures of the magnetoresistive element according to the present embodiment. FIG. 22 is a diagram illustrating an example of a magnetoresistive element 210E, in which an in-plane magnetization film that is stable when the magnetization direction is within the film plane, is used for a free layer 213, in which (a) is a top view of the magnetoresistive element 210E, and (b) is a perpendicular cross-sectional view parallel to the major axis direction (X direction in this example) of the magnetoresistive element 210E. Meanwhile, FIG. 23 is a diagram illustrating a magnetoresistive element 210C, in which a perpendicular magnetization film that is stable when the magnetization direction is perpendicular to a film surface (Z direction in this example), is used for a free layer 218, in which (a) is a top view of the magnetoresistive element 210C, and (b) is a perpendicular cross-sectional view of the magnetoresistive element 210C. Note that, similarly to the first embodiment, the magnetization directions of the free layers 213 and 218 are variable depending on the external magnetic field, whereas the magnetization directions of the fixed layers 211 and 216 are fixed.

As illustrated in FIG. 22, the upper surface shape of the magnetoresistive element 210E in which the in-plane magnetization film is used for the free layer 213 has a line-symmetrical shape having a longitudinal direction in an in-plane direction and a straight line perpendicular to the longitudinal direction and passing through the center point, the straight line being the line of symmetry. Illustrated in FIG. 22 is a case where the upper surface shape of the magnetoresistive element 210E is an elliptical shape having the major axis in the in-plane direction. However, it is not limited thereto, and various modifications may be made such as a polygon having a longitudinal direction in an in-plane direction such as a rectangle. In addition, the magnetization direction of the fixed layer 211 of the magnetoresistive element 210E is set to a direction parallel to the longitudinal direction. Note that a nonmagnetic layer 212 is disposed between the fixed layer 211 and the free layer 213.

Meanwhile, as illustrated in FIG. 23, the upper surface shape of the magnetoresistive element 210C in which the perpendicular magnetization film is used for the free layer 218 has a point-symmetrical shape having no longitudinal direction in the in-plane direction with the center point being the point of symmetry. Illustrated in FIG. 23 is a case where the upper surface shape of the magnetoresistive element 210E is a round shape having no major axis in an in-plane direction. However, it is not limited thereto, and various modifications may be made such as a polygon having no longitudinal direction in an in-plane direction such as a square or a regular hexagon. In addition, the magnetization direction of the fixed layer 216 of the magnetoresistive element 210C is set to a direction perpendicular to the formation surfaces of the layers. Note that a nonmagnetic layer 217 is disposed between the fixed layer 216 and the free layer 218.

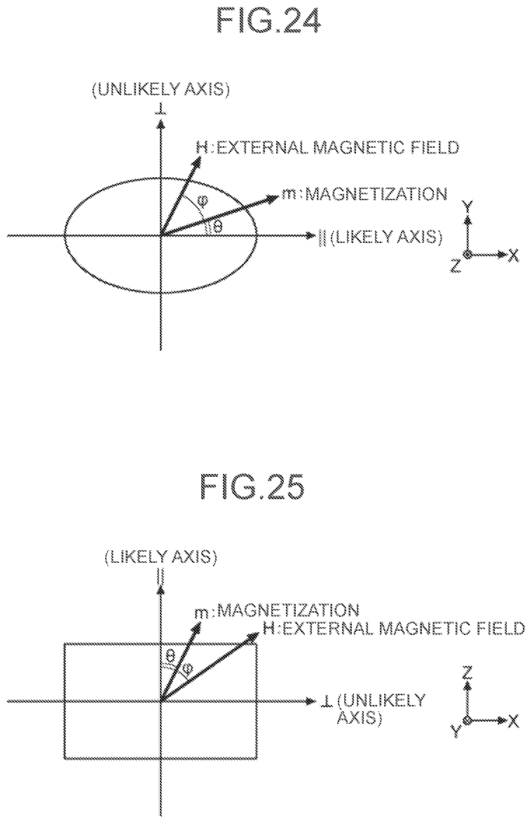

FIG. 24 is a diagram illustrating the relationship between the magnetization direction of the free layer 213 in the magnetoresistive element 210E illustrated in FIG. 22 and the direction of an external magnetic field. Note that illustrated in FIG. 24 is the magnetoresistive element 210E as viewed from above. Meanwhile, FIG. 25 is a diagram illustrating the relationship between the magnetization direction of the free layer 218 in the magnetoresistive element 210C illustrated in FIG. 23 and the direction of the external magnetic field. Note that illustrated in FIG. 25 is a vertical cross-sectional view of the magnetoresistive element 210C.

As illustrated in FIG. 24, in the case where the free layer 213 is the in-plane magnetization film and the element shape is an elliptical shape having the major axis and the minor axis, the magnetization direction of the free layer 213 is likely to be oriented in the major axis direction. Therefore, in the present description, the magnetization direction (major axis direction) in which the free layer 213 is likely to be oriented is referred to as a (magnetization) likely axis. Conversely, in the example illustrated in FIG. 22, the magnetization direction of the free layer 213 is unlikely to be oriented in the minor axis direction. Therefore, in the present description, a magnetization direction (minor axis direction) in which the free layer 213 is unlikely to be oriented is referred to as a (magnetization) unlikely axis.

On the other hand, as illustrated in FIG. 25, in a case where the free layer 218 is the perpendicular magnetization film, the likely axis is in the direction perpendicular to the film surface, and the unlikely axis is in the in-plane direction of the film. Note that in a case where the element shape is circular, any direction is equivalent as long as it is in the in-plane direction of the film.

Here, in both the case illustrated in FIG. 24 and the case illustrated in FIG. 25, an angle formed by the direction of magnetization m and the likely axis is denoted by θ, and an angle formed by the direction of an external magnetic field H and the likely axis is denoted by ϕ. In addition, how likely the magnetization is to be oriented in the likely axis direction is determined by a magnetic anisotropy constant K. The larger K is, the more likely the magnetization is to be oriented in the likely axis direction. The magnetic energy E of the magnetization depends on the direction of the magnetization and the external magnetic field. Therefore, regardless of whether it is the in-plane magnetization film or the perpendicular magnetization film, the magnetic energy E can be expressed by the following Equation (5). In Equation (5), V denotes the volume of the free layer, and μ₀ denotes the permeability of a vacuum.

$$E = K V s i {n}^{2} ( θ ) - {μ}_{0} {M}_{s} V H cos ( ϕ - θ ) \qquad ( 5 )$$

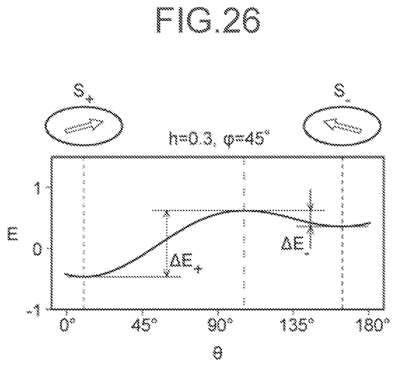

FIG. 26 is a graph illustrating an example of θ dependency of magnetic energy E when an external magnetic field H having ϕ=45 degrees is applied. In the example illustrated in FIG. 26, a state in which the magnetization is oriented in the positive direction of a substantially likely axis is defined as S₊, and a state in which the magnetization is oriented in the negative direction is defined to as S₋. At magnetization angles θ of S₊ and S₋, E has the minimum value. For a state change from S₊ to S₋ or from S₋ to S₊, it is necessary to pass the maximum value of E at θ≈90 degrees. The differences between the maximum values and the minimum values are each defined as ΔE₊ and ΔE₋. The probability that these state changes occur is expressed by the Arrhenius equation using ΔE₊ and ΔE₋. Then, the probability of being in the state S₊ at a certain time point denoted as P₊, and the probability of being in the state S₋ as P₋. As a result of various studies, the present inventor has found that P₊ and P₋ can be expressed by the following Equations (6) and (7).

$$1 / {P}_{+} = exp ( - 2 {μ}_{0} {M}_{s} V {H}_{\vert \vert} / {k}_{B} T ) + 1 \qquad ( 6 )$$

$$1 / {P}_{-} = exp ( + 2 {μ}_{0} {M}_{s} V {H}_{\vert \vert} / {k}_{B} T ) + 1 \qquad ( 7 )$$

In Equations (6) and (7), KB denotes the Boltzmann constant, and T denotes the absolute temperature. Incidentally, Hu denotes a likely axis component of H. Defining output signals S from the magnetoresistive elements 210E and 210C as (P₊-P₋), (P₊-P₋) is equal to the difference in the staying time of being in each of the states. Therefore, S can be expressed by the following Equation (8) by using Equations (6) and (7).

$$S = tanh ( {μ}_{0} {M}_{s} {VH}_{\vert \vert} / {k}_{B} T ) \qquad ( 8 )$$

That is, it can be seen that only a component along the likely axis direction can be detected from an external magnetic field at any angle.

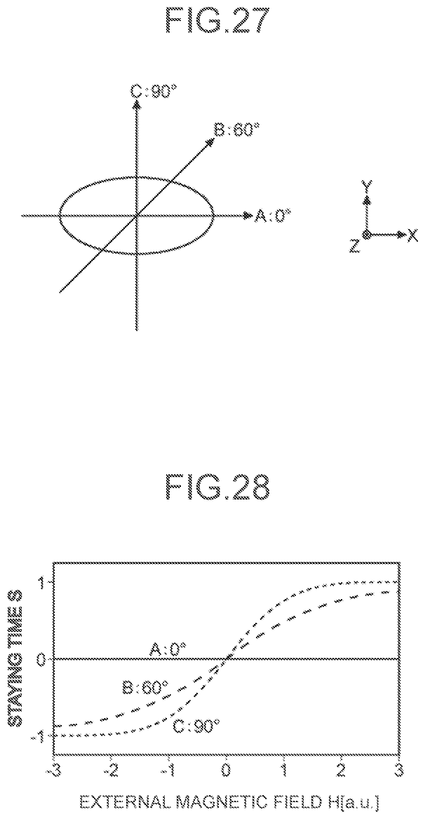

In FIGS. 27 and 28, the relationship between the direction of the external magnetic field and an output signal (difference in staying times) S in the case where the in-plane magnetization film is used for the free layer 213 is illustrated. In FIGS. 27 and 28, A illustrates a case where the direction of the external magnetic field H is parallel to the likely axis (ϕ=0°, B illustrates a case where the direction of the external magnetic field H is inclined with respect to the likely axis (ϕ=60°), and C illustrates a case where the direction of the external magnetic field H is perpendicular to the likely axis (ϕ=90°.

As illustrated in FIGS. 27 and 28, the sensitivity is the highest in A where the direction of the external magnetic field H is equivalent to the likely axis, and conversely, the sensitivity is zero in C where the direction of the external magnetic field H is perpendicular to the likely axis, namely, equal to the unlikely axis.

The magnetoresistive elements 210E and 210C including the likely axis and the unlikely axis in this manner have directivity in the sensitivity to an external magnetic field. Therefore, in the present embodiment, by combining magnetoresistive elements having likely axes in different directions, it is made possible to detect not only the magnitude of the external magnetic field but also the direction of the external magnetic field.

### 2.2 Variations of Magnetoresistive Element

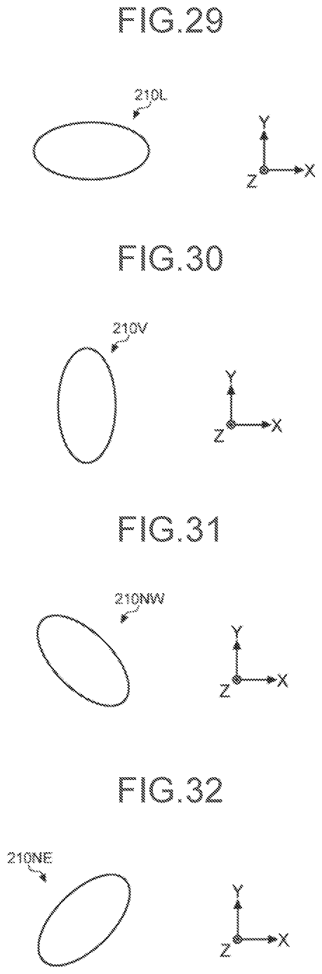

FIGS. 29 to 33 are top views illustrating some of variations of the magnetoresistive element according to the present embodiment.

FIG. 29 is a top view illustrating a planar structure example of a magnetoresistive element 210L in which the likely axis is parallel to the lateral direction (X direction) among the magnetoresistive elements 210E in which the in-plane magnetization film having the likely axis and the unlikely axis in the in-plane direction is used for the free layer 213. Therefore, according to the magnetoresistive element 210L, it is possible to detect the component in the X direction in the external magnetic field H with high sensitivity.

FIG. 30 is a top view illustrating a planar structure example of a magnetoresistive element 210V in which the likely axis is parallel to the longitudinal direction (Y direction) among the magnetoresistive elements 210E. Therefore, according to the magnetoresistive element 210V, it is possible to detect the component in the Y direction in the external magnetic field H with high sensitivity.

FIG. 31 is a top view illustrating a planar structure example of a magnetoresistive element 210NW parallel to a direction in which the likely axis is inclined counterclockwise by 135° with respect to the X direction (hereinafter, also referred to as −XY direction or left oblique direction) among the magnetoresistive elements 210E. The magnetoresistive element NW is a variation for complementing the detection of a magnetic field in the in-plane direction by the magnetoresistive element 210L and the magnetoresistive element 210V and can detect a component in the left oblique direction in the external magnetic field H with high sensitivity.

FIG. 32 is a top view illustrating a planar structure example of a magnetoresistive element 210NE parallel to a direction in which the likely axis is inclined counterclockwise by 45° with respect to the X direction (hereinafter, also referred to as +XY direction or right oblique direction) among the magnetoresistive elements 210E. Similarly to the magnetoresistive element NW, the magnetoresistive element NE is a variation for complementing the detection of a magnetic field in the in-plane direction by the magnetoresistive element 210L and the magnetoresistive element 210V and can detect the component in the left oblique direction in the external magnetic field H with high sensitivity.

FIG. 33 is a top view illustrating a planar structure example of the magnetoresistive element 210C in which the perpendicular magnetization film having the likely axis and the unlikely axis in the perpendicular direction is used for the free layer 218. Therefore, according to the magnetoresistive element 210C, a component in the vertical direction (Z direction) in the external magnetic field H can be detected with high sensitivity.

By appropriately combining the magnetoresistive elements 210L, 210V, 210NW, 210NE, and 210C having likely axes oriented in different directions as described above, it is possible to detect the direction of the external magnetic field with high sensitivity.

### 2.3 Array Example of Magnetoresistive Elements

Next, an array of the magnetoresistive elements according to the embodiment will be described with some examples.

### 2.3.1 First Example

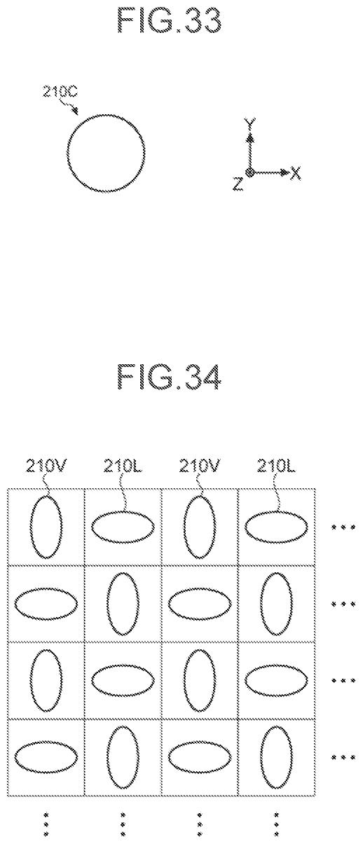

FIG. 34 is a plan layout view illustrating an array example of magnetoresistive elements that detect an external magnetic field in two axes (X axis and Y axis) in a plane, the magnetoresistive elements according to a first example of the embodiment. As illustrated in FIG. 34, in the first example, the magnetoresistive elements 210L having high sensitivity to a magnetic field component in the X direction and the magnetoresistive elements 210V having high sensitivity to a magnetic field component in the Y direction are alternately arrayed in a checkered pattern. By arranging the magnetoresistive elements 210L and the magnetoresistive elements 210V evenly in this manner, the magnitude and direction of the external magnetic field H in the in-plane direction can be detected with high sensitivity. Note that the array pattern is not limited to the pattern illustrated in FIG. 34, and various modifications may be made, such as arraying the magnetoresistive elements 210L and 210V in every other row or every other column, as long as the magnetoresistive elements 210L and 210V can be uniformly and evenly arrayed.

### 2.3.2 Second Example

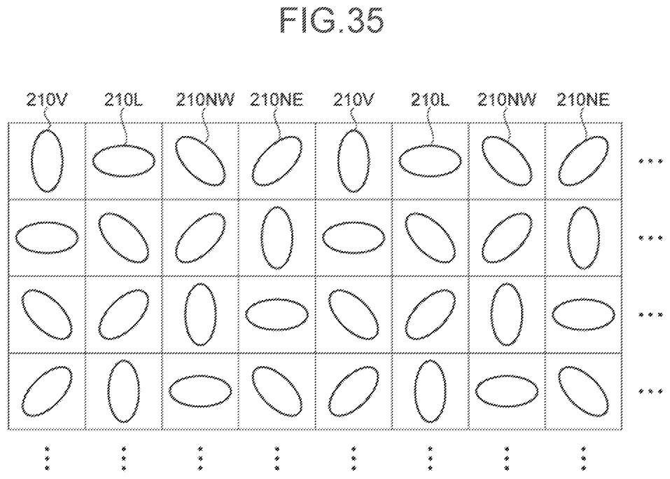

FIG. 35 is a plan layout view illustrating an array example of magnetoresistive elements that detect an external magnetic field in two axes (X axis and Y axis) in a plane, the magnetoresistive elements according to a second example of the embodiment. As illustrated in FIG. 35, in the second example, in addition to the magnetoresistive elements 210L and 210V, the magnetoresistive elements 210NW having high sensitivity to a magnetic field component in the −XY direction and magnetoresistive elements 210NE having high sensitivity to a magnetic field component in the +XY direction are alternately arrayed. In this manner, by arranging the magnetoresistive elements 210L, 210V, 210NW, and 210NE evenly, it is possible to detect the magnitude and the direction of the external magnetic field H in the in-plane direction with higher sensitivity. Note that the array pattern is not limited to the pattern illustrated in FIG. 35, and various modifications may be made, such as arraying the magnetoresistive elements 210L, 210V, 210NW, and 210NE in every other row or every other column, as long as the magnetoresistive elements 210L, 210V, 210NW, and 210NE can be uniformly and evenly arrayed.

### 2.3.3 Third Example

FIG. 36 is a plan layout view illustrating an array example of magnetoresistive elements that detect an external magnetic field in three axes (X axis, Y axis, and X axis), the magnetoresistive elements according to a third example of the embodiment. As illustrated in FIG. 36, in the third example, on the basis of the array example according to the first example, in addition to the magnetoresistive elements 210L and 210V according to the first example, the magnetoresistive elements 210C having high sensitivity to a magnetic field component in the z direction are alternately arrayed. By arranging the magnetoresistive elements 210L and 210V that detect a magnetic field component in the in-plane direction with high sensitivity and the magnetoresistive elements 210C that detect a magnetic field component in the Z direction with high sensitivity evenly in this manner, it is possible to detect the magnitude and the direction of the external magnetic field H not only in the in-plane direction but also in the X direction with high sensitivity. Note that the array pattern is not limited to the pattern illustrated in FIG. 36, and various modifications may be made, such as arraying the magnetoresistive elements 210L, 210V, and 210C in every other row or every other column, as long as the magnetoresistive elements 210L, 210V, and 210C can be uniformly and evenly arrayed.

### 2.3.4 Fourth Example

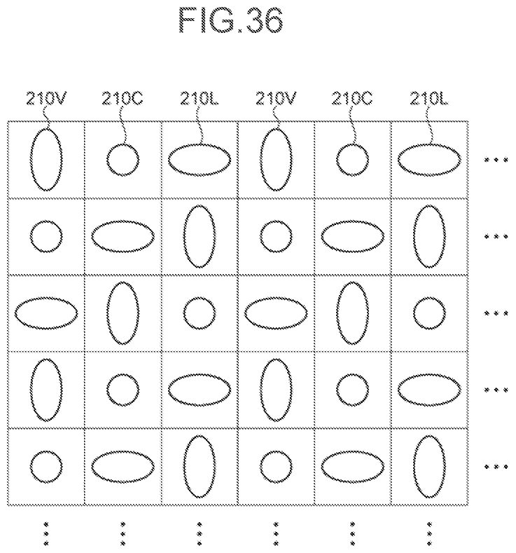

FIG. 37 is a plan layout view illustrating an array example of magnetoresistive elements that detect an external magnetic field in three axes (X axis, Y axis, and X axis), the magnetoresistive elements according to a fourth example of the embodiment. As illustrated in FIG. 37, in the fourth example, on the basis of the array example according to the second example, in addition to the magnetoresistive elements 210L, 210V, 210NW, and 210NE according to the second example, the magnetoresistive elements 210C having high sensitivity to a magnetic field component in the Z direction are alternately arrayed. By arranging the magnetoresistive elements 210L, 210V, 210NW, and 210NE that detect a magnetic field component in the in-plane direction with high sensitivity and the magnetoresistive elements 210C that detect a magnetic field component in the Z direction with high sensitivity evenly in this manner, it is possible to detect the magnitude and the direction of the external magnetic field H not only in the in-plane direction but also in the X direction with higher sensitivity. Note that the array pattern is not limited to the pattern illustrated in FIG. 37, and various modifications may be made, such as arraying the magnetoresistive elements 210L, 210V, 210NW, 210NE, and 210C in every other row or every other column, as long as the magnetoresistive elements 210L, 210V, 210NW, 210NE, and 210C can be uniformly and evenly arrayed.

### 2.4 Exemplary Manufacturing Method

Next, an example of a manufacturing method of the magnetism detection device according to the present embodiment will be described.

Among the variations of the magnetoresistive elements described above with reference to FIGS. 29 to 33, the magnetoresistive elements 210L, 210V, 210NW, and 210NE (variations of the magnetoresistive element 210E) can be formed and processed by the same process since the in-plane magnetization film is used for the free layer 213 in all the magnetoresistive elements. Meanwhile, since the perpendicular magnetization film is used for the free layer 218, the magnetoresistive elements 210C cannot be formed by the same process as the magnetoresistive elements 210E and needs to be formed and processed by another process.

Therefore, in the following description, a case will be described with an example in which a magnetoresistive element 210E using the in-plane magnetization film for the free layer 213 and a magnetoresistive element 210C using the perpendicular magnetization film for the free layer 218 are formed in the same layer.

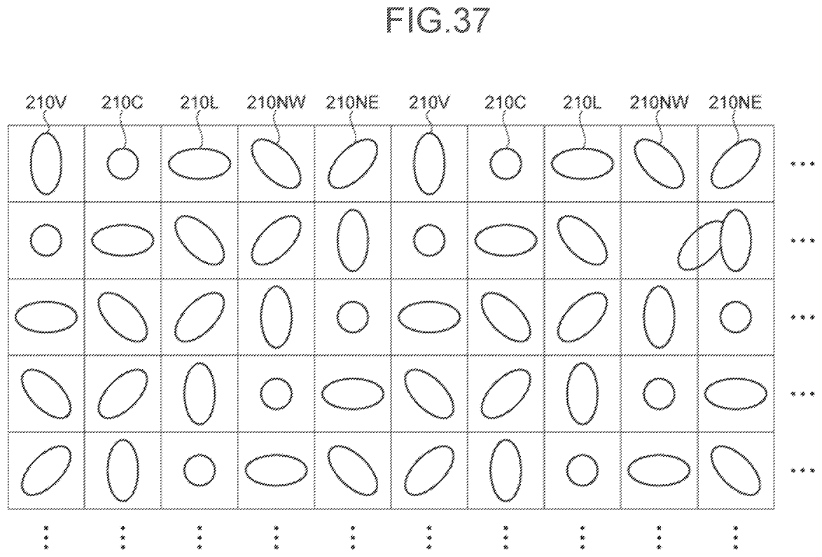

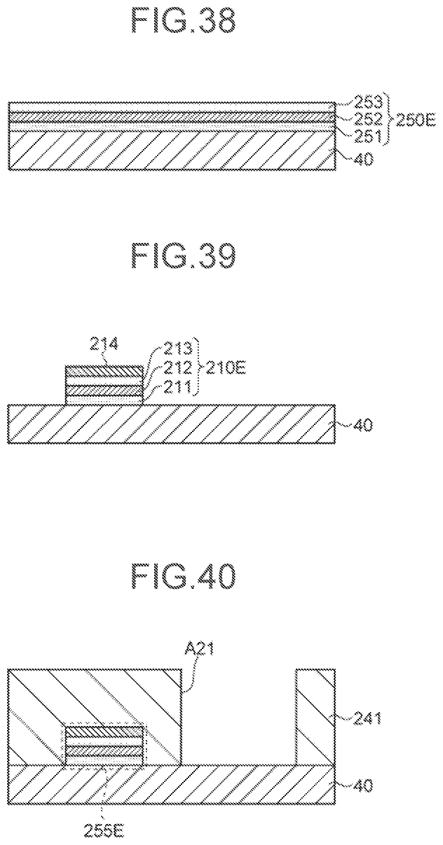

FIGS. 38 to 46 are process cross-sectional views illustrating an exemplary manufacturing method of the magnetism detection device according to the embodiment. Note that, in the following description, attention is paid to some basic units of the magnetism detection device to facilitate understanding. In the following description, steps similar to the manufacturing steps described by referring to FIGS. 14 to 19 in the first embodiment are cited.

In the present manufacturing method, as illustrated in FIG. 38, similarly to the step described by referring to FIG. 14 in the first embodiment, first, a laminated film 250E in which a first layer 251 to be processed into the fixed layer 211 in the magnetoresistive element 210E, a second layer 252 to be processed into the nonmagnetic layer 212, and a third layer 253 to be processed into the free layer 213 are laminated in the order mentioned is formed on the entire surface of a base substrate 40 including peripheral circuits. Note that the third layer 253 may be an in-plane magnetization film.

Next, as illustrated in FIG. 39, similarly to the steps described by referring to FIGS. 15 and 16 in the first embodiment, the laminated film 50 is processed into a mesa-shaped magnetoresistive element 210E by using, for example, the photolithography technology and the etching technology, and an upper electrode 214 is formed on the upper surface of the magnetoresistive element 10.

Next, an insulating layer 241 is formed in such a manner as to embed a structure 255E including the magnetoresistive element 210E and the upper electrode 214 by using, for example, the CVD method or the sputtering method. Subsequently, as illustrated in FIG. 40, a trench A21 for forming the magnetoresistive element 210C is formed in the insulating layer 241 that has been formed by using, for example, the photolithography technology and the etching technology. Note that an upper surface of the insulating layer 241 may be leveled by, for example, CMP or the like.

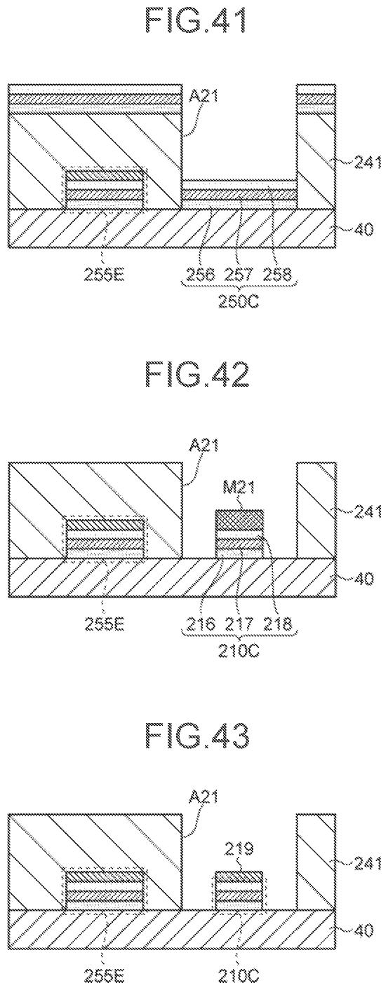

Next, as illustrated in FIG. 41, a laminated film 250C in which a first layer 256 to be processed into the fixed layer 216 in the magnetoresistive element 210C, a second layer 257 to be processed into the nonmagnetic layer 217, and a third layer 258 to be processed into the free layer 218 are laminated in the order mentioned is formed on the base substrate 40 exposed in the trench A21. Note that the third layer 258 may be the perpendicular magnetization film. In addition, the laminated film 250C formed on the insulating layer 241 may be removed by the lift-off technology, CMP, or the like.

Next, as illustrated in FIG. 42, for example, photolithography or the like is used to form a mask M21 on the laminated film 250C, and the laminated film 250C exposed from the mask M21 is dug using etching technology such as RIE to form the magnetoresistive element 210C of the mesa shape.

Next, as illustrated in FIG. 43, for example, upper electrodes 219 are formed on the upper surfaces of the magnetoresistive elements 210C by using the lift-off technology or the like.

Next, as illustrated in FIG. 44, the trench A21 of the insulating layer 241 is buried by using, for example, the CVD method or the sputtering method, thereby forming an insulating layer 242 that covers the structure 255E including the magnetoresistive element 210E and the upper electrode 214 and a structure 255C including the magnetoresistive element 210C and the upper electrode 219. Note that an upper surface of the insulating layer 242 may be leveled by, for example, CMP or the like.

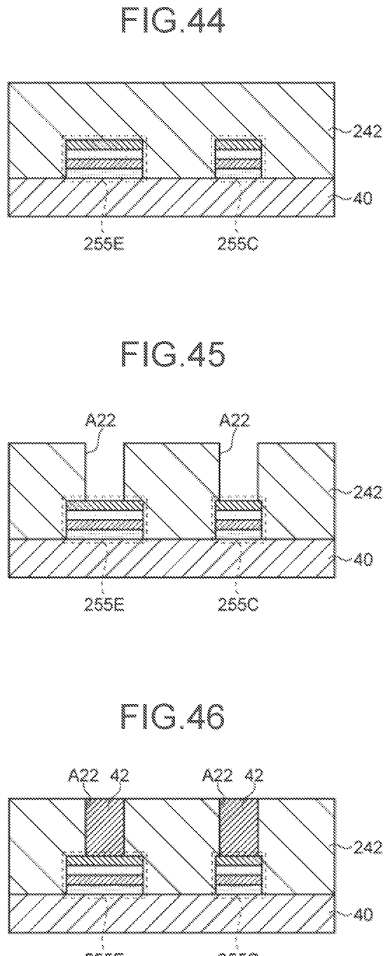

Next, as illustrated in FIG. 45, openings A22 for exposing parts of the upper surfaces of the upper electrodes 214 and 219 are formed by using, for example, the photolithography technology and the etching technology.

Next, as illustrated in FIG. 46, pieces of wiring 42 connected to the upper electrodes 214 or 219 are embedded in the openings A22. Thereafter, a wire connecting the pieces of wiring 42 to a power supply voltage VDD is formed on the insulating layer 242, thereby manufacturing the magnetism detection device according to the present embodiment. Note that, similarly to the first embodiment, in a case where a plurality of magnetism detection devices is collectively built in one wafer, a step of singulating and packaging the wafer into semiconductor chips may be executed. In addition, in a case where the magnetism detection device (block) has a configuration in which a plurality of semiconductor chips is stacked, a step of bonding the semiconductor chips may be executed.

### 2.4.1 Modification of Manufacturing Method

Next, a modification of the manufacturing method according to the present embodiment will be described. In the present modification, a case where the magnetoresistive element 210E and the magnetoresistive element 210C are formed in different layers will be described as an example.

FIGS. 47 to 53 are process cross-sectional views illustrating an exemplary manufacturing method of the magnetism detection device according to the embodiment. Note that, in the following description, attention is paid to some basic units of the magnetism detection device to facilitate understanding. In the following description, steps similar to the manufacturing steps described above by referring to FIGS. 38 to 46 are cited.

In the present manufacturing method, first, a structure 255E including a magnetoresistive element 210E and an upper electrode 214 is formed on a base substrate 40 including peripheral circuits in steps similar to the steps described above by referring to FIGS. 38 to 39.

Next, an insulating layer 241 is formed in such a manner as to embed a structure 255E including the magnetoresistive element 210E and the upper electrode 214 by using, for example, the CVD method or the sputtering method. Subsequently, as illustrated in FIG. 47, a trench A23 for exposing a lower electrode in the base substrate 40 is formed in the insulating layer 241 that has been formed by using, for example, the photolithography technology and the etching technology. Note that an upper surface of the insulating layer 241 may be leveled by, for example, CMP or the like.

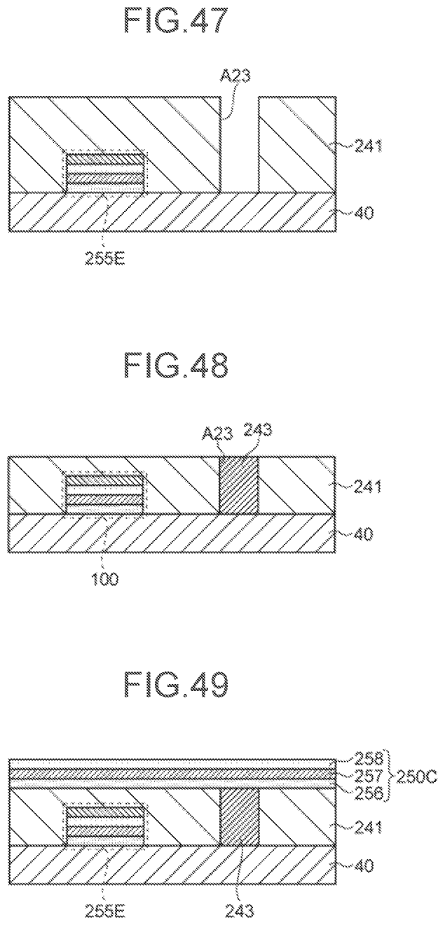

Next, as illustrated in FIG. 48, wiring 243 connected to the lower electrode of the base substrate 40 is embedded in the trench A23 of the insulating layer 241.

Next, as illustrated in FIG. 49, a laminated film 250C in which a first layer 256 to be processed into the fixed layer 216 in the magnetoresistive element 210C, a second layer 257 to be processed into the nonmagnetic layer 217, and a third layer 258 to be processed into the free layer 218 are laminated in the order mentioned is formed on the insulating layer 241. Note that the third layer 258 may be the perpendicular magnetization film.

Next, for example, photolithography or the like is used to form a mask M23 on the laminated film 250C, and the laminated film 250C exposed from the mask M23 is dug using etching technology such as RIE to form the magnetoresistive element 210C of the mesa shape. Subsequently, as illustrated in FIG. 50, for example, upper electrodes 219 are formed on the upper surfaces of the magnetoresistive elements 210C by using the lift-off technology or the like.

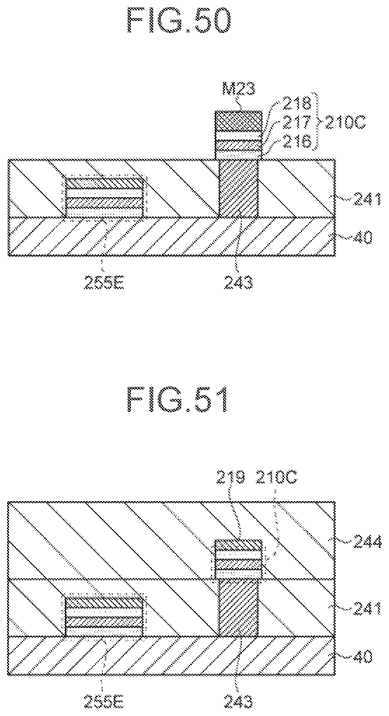

Next, as illustrated in FIG. 51, an insulating layer 244 is formed in such a manner as to embed structures 255C each including a magnetoresistive element 210C and an upper electrode 219 by using, for example, the CVD method or the sputtering method. Note that an upper surface of the insulating layer 244 may be leveled by, for example, CMP or the like.

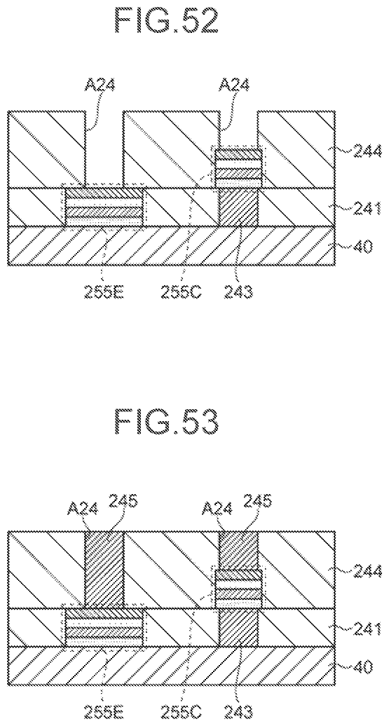

Next, as illustrated in FIG. 52, openings A24 for exposing parts of the upper surfaces of the upper electrodes 214 and 219 are formed by using, for example, the photolithography technology and the etching technology.

Next, as illustrated in FIG. 53, pieces of wiring 245 connected to the upper electrodes 214 or 219 are embedded in the openings A24. Thereafter, a wire connecting the pieces of wiring 42 to a power supply voltage VDD is formed on the insulating layer 244, thereby manufacturing the magnetism detection device according to the present embodiment.

### 2.5 Action and Effects

As described above, according to the present embodiment, since the magnetism detection device is structured by appropriately combining the magnetoresistive elements having likely axes in different directions, it is possible to implement the magnetism detection device capable of detecting not only the magnitude of the external magnetic field but also the direction of the external magnetic field.

Other configurations, operations, manufacturing method, and effects may be similar to those of the above-described embodiment, and thus detailed description is omitted here.

### 3. THIRD EMBODIMENT

Next, a third embodiment will be described in detail by referring to the drawings. In the third embodiment, a magnetism detection device structured using the magnetoresistive elements according to the above embodiment will be described more specifically. Note that, in the present embodiment, a case based on the structure described by referring to FIG. 12 in the first embodiment is described as an example; however, it is not limited thereto.

FIG. 54 is a block diagram illustrating an exemplary schematic configuration of a magnetism detection device according to the embodiment. As illustrated in FIG. 54, a magnetism detection device 100 includes, for example, a detection circuit array 101, a vertical drive circuit 102, a signal processing circuit 103, and a magnetism detection unit 109. In the present description, the vertical drive circuit 102, the signal processing circuit 103, a system control circuit 105, and the magnetism detection unit 109 are also referred to as peripheral circuits.

The detection circuit array 101 is an array unit in which the detection circuits 110b (see FIG. 12) according to the above-described first embodiment are arrayed in a two-dimensional lattice pattern. Note that a magnetoresistive element in each of the detection circuits 110b may be any of the magnetoresistive element 10 according to the first embodiment, the magnetoresistive elements 210L, 210V, 210NW, 210NE, or 210C according to the second embodiment.

The vertical drive circuit 102 includes a shift register, an address decoder, or the like and drives the detection circuits 110b of the detection circuit array 101 simultaneously, row by row, or in other manners. That is, the vertical drive circuit 102 constitutes a drive unit that controls the operation of each of the detection circuits 110b of the detection circuit array 101 together with the system control circuit 105 that controls the vertical drive circuit 102. The vertical drive circuit 102 includes, for example, two scanning systems of a read scanning system and a sweep scanning system.

The read scanning system sequentially and selectively scans the detection circuit array 101 row by row in order to read a signal from each of the detection circuits 110b. The signal read from each of the detection circuits 110b is an analog signal. The sweep scanning system performs sweep scanning on a reading row, on which read scanning is to be performed by the read scanning system, earlier than the read scanning by a predetermined period of time.

By the sweep scanning by the sweep scanning system, unnecessary charges are swept out from detection circuits 110b of the reading row, whereby the detection circuits 110b are reset.

Signals output from the detection circuits 110b of the row selectively scanned by the vertical drive circuit 102 are input to the signal processing circuit 103 through a signal line of each column. The signal processing circuit 103 performs predetermined signal processing on a signal output from each detection circuit 110b of the selected row for each column of the detection circuit array 101 and temporarily holds the signals after the signal processing. For example, the signal processing circuit 103 includes AD conversion circuits 25, converts analog signals read from the respective detection circuits 110b into digital signals, and outputs the digital signals as an output signal SIG.

The system control circuit 105 includes a timing generator that generates various timing signals and others and performs drive control of the vertical drive circuit 102, the signal processing circuit 103, and others on the basis of various types of timing generated by the timing generator.

The magnetism detection unit 109 detects the magnitude (direction in the second embodiment) of the external magnetic field by performing predetermined processing on the signal output from the signal processing circuit 103. For example, the magnetism detection unit 109 may integrate the output signal SIG read from the detection circuits 110b and converted into digital signals, calculate an integrated value of each of the first staying time and the second staying time of all the magnetoresistive elements 10 from a value obtained from the integration, and detect the magnitude of the external magnetic field on the basis of a difference between the integrated value of the first staying time and the integrated value of the second staying time that have been calculated.

Note that, as in the second embodiment, in a case where each of the detection circuits 110b includes the magnetoresistive elements 210E and 210C having likely axes in different directions, signals to be integrated may be read from magnetoresistive elements 210E or 210C having likely axes in the same direction.

Other configurations, operations, and effects may be similar to those of the above-described embodiments, and thus detailed description is omitted here.

Although the embodiments of the disclosure have been described above, the technical scope of the disclosure is not limited to the above embodiments as they are, and various modifications can be made without departing from the gist of the disclosure. In addition, components of different embodiments and modifications may be combined as appropriate.

Furthermore, the effects of the embodiments described herein are merely examples and are not limiting, and other effects may be achieved.

Note that the present technology can also have the following configurations.

(1)

A magnetism detection device including:
a magnetoresistive element; and
a detection unit that detects an external magnetic field on a basis of a resistance value of the magnetoresistive element,
wherein the magnetoresistive element includes:
a fixed layer having a fixed magnetization direction;
a nonmagnetic layer disposed on the fixed layer; and
a free layer disposed on the nonmagnetic layer, the free layer having a magnetization direction varying with time, and
a magnetic anisotropy axis of the free layer is parallel to the magnetization direction of the fixed layer.
   (2)

The magnetism detection device according to (1),
wherein the magnetoresistive element outputs at least one of information related to first staying time, during which a state in which the magnetization direction of the free layer is parallel to the magnetization direction of the fixed layer is maintained, or information related to second staying time, during which a state in which the magnetization direction of the free layer is antiparallel to the magnetization direction of the fixed layer is maintained, and
the detection unit detects the external magnetic field on a basis of a difference between the first staying time and the second staying time specified from at least one of the information related to the first staying time and the information related to the second staying time.
   (3)

The magnetism detection device according to (2),
wherein the first staying time and the second staying time are within a range of 0.1 microseconds to 10 milliseconds.
   (4)

The magnetism detection device according to (2) or (3), further including:
a plurality of the magnetoresistive elements,
wherein the detection unit detects the external magnetic field on a basis of a difference between an integrated value of the first staying time and an integrated value of the second staying time in each of the plurality of magnetoresistive elements.
   (5)

The magnetism detection device according to any one of (2) to (4), further including:
a conversion unit that converts a charge having flowed through the magnetoresistive element into a digital value,
wherein the detection unit specifies the first staying time and the second staying time in the magnetoresistive element on a basis of the digital value.
   (6)

The magnetism detection device according to (5), further including:
a low-pass filter disposed between the magnetoresistive element and the conversion unit.
   (7)

The magnetism detection device according to any one of (2) to (5), further including:
a gate circuit that opens and closes depending on a resistance value of the magnetoresistive element,
wherein the detection unit specifies the first staying time and the second staying time on a basis of a number of pulses of a pulse signal that has been conducted through the gate circuit during a period in which the gate circuit has been in an open state.
   (8)

The magnetism detection device according to any one of (2) to (5), further including:
an accumulation unit that accumulates charges having flowed through the magnetoresistive element,
wherein the detection unit specifies the first staying time and the second staying time on a basis of an amount of the charges accumulated in the accumulation unit.
   (9)

The magnetism detection device according to any one of (2) to (5),
wherein the detection unit specifies the first staying time and the second staying time on a basis of an amount of charges accumulated in the magnetoresistive element.
   (10)

The magnetism detection device according to any one of (1) to (9), further including:
an element assembly including a plurality of the magnetoresistive elements connected in parallel and/or in series,
wherein the detection unit detects an external magnetic field on a basis of a resistance value of the element assembly.
   (11)

The magnetism detection device according to (10),
wherein the element assembly is integrated on a single semiconductor chip or a plurality of semiconductor chips.
   (12)

The magnetism detection device according to any one of (1) to (11), further including:
a plurality of the magnetoresistive elements arrayed in a two-dimensional lattice pattern; and
a drive circuit that drives the plurality of magnetoresistive elements row by row or column by column.
   (13)

The magnetism detection device according to any one of (1) to (11), further including:
a plurality of the magnetoresistive elements; and
a plurality of charge-coupled elements that sequentially transfers and aggregates charges having flowed through the respective magnetoresistive elements.
   (14)

The magnetism detection device according to any one of (1) to (13), further including:
a plurality of the magnetoresistive elements,
wherein each of the magnetoresistive elements has a likely axis to which the magnetization direction of the free layer is more likely to be oriented than to other directions and an unlikely axis to which the magnetization direction of the free layer is less likely to be oriented than to other directions, and
a direction of the likely axis of at least one of the plurality of magnetoresistive elements is different from a direction of the likely axis of another magnetoresistive element.
   (15)

The magnetism detection device according to (14),
wherein, in at least one of the plurality of magnetoresistive elements, a length in a direction of the likely axis is longer than a length in a direction of the unlikely axis.
   (16)

The magnetism detection device according to (14) or (15),
wherein a planar shape of at least one of the plurality of magnetoresistive elements is an elliptical shape.
   (17)

The magnetism detection device according to any one of (14) to (16),
wherein a planar shape of at least one of the plurality of magnetoresistive elements is circular.
   (18)

The magnetism detection device according to any one of (14) to (17),
wherein the plurality of magnetoresistive elements includes:
a first magnetoresistive element in which a direction of the likely axis is a first direction; and
a second magnetoresistive element in which a direction of the likely axis is a second direction different from the first direction by 90°.
   (19)

The magnetism detection device according to (18),
wherein the plurality of magnetoresistive elements includes:
a third magnetoresistive element in which a direction of the likely axis is a third direction different from the first direction by 45° and different from the second direction by −45°; and
a fourth magnetoresistive element in which a direction of the likely axis is a fourth direction different from the first direction by 135° and different from the second direction by 45°.
   (20)

The magnetism detection device according to (18) or (19),
wherein the plurality of magnetoresistive elements further includes a fifth magnetoresistive element in which a direction of the likely axis is a fifth direction different by 90° from each of the first direction and the second direction.

### REFERENCE SIGNS LIST

10, 210C, 210E, 210L, 210NW, 210NE, 210V MAGNETORESISTIVE ELEMENT
11, 211, 216 FIXED LAYER
12, 212, 217 NONMAGNETIC LAYER
13, 213, 218 FREE LAYER
14, 214, 219 UPPER ELECTRODE
15, 255C, 255E STRUCTURE
21 COMPARATOR
22 VERTICAL TRANSFER CCD
23 HORIZONTAL TRANSFER CCD
24 CHARGE-VOLTAGE CONVERSION CIRCUIT
25 AD CONVERSION CIRCUIT
26 LOW-PASS FILTER
40 BASE SUBSTRATE
41, 241, 242, 244 INSULATING LAYER
42, 243, 245 WIRING
50, 250C, 250E LAMINATED FILM
51, 251, 256 FIRST LAYER
52, 252, 257 SECOND LAYER
53, 253, 258 THIRD LAYER
100 MAGNETISM DETECTION DEVICE
101 DETECTION CIRCUIT ARRAY
102 VERTICAL DRIVE CIRCUIT
103 SIGNAL PROCESSING CIRCUIT
105 SYSTEM CONTROL CIRCUIT
109 MAGNETISM DETECTION UNIT
110b, 110A, 110B, 110C DETECTION CIRCUIT
C2 CAPACITOR
R1 to R4 RESISTOR
T1, T2 CMOS TRANSISTOR

1. A magnetism detection device including:
a magnetoresistive element; and
a detection unit that detects an external magnetic field on a basis of a resistance value of the magnetoresistive element,
wherein the magnetoresistive element includes:
a fixed layer having a fixed magnetization direction;
a nonmagnetic layer disposed on the fixed layer; and
a free layer disposed on the nonmagnetic layer, the free layer having a magnetization direction varying with time, and
a magnetic anisotropy axis of the free layer is parallel to the magnetization direction of the fixed layer.

2. The magnetism detection device according to claim 1,
wherein the magnetoresistive element outputs at least one of information related to first staying time, during which a state in which the magnetization direction of the free layer is parallel to the magnetization direction of the fixed layer is maintained, or information related to second staying time, during which a state in which the magnetization direction of the free layer is antiparallel to the magnetization direction of the fixed layer is maintained, and
the detection unit detects the external magnetic field on a basis of a difference between the first staying time and the second staying time specified from at least one of the information related to the first staying time and the information related to the second staying time.

3. The magnetism detection device according to claim 2,
wherein the first staying time and the second staying time are within a range of 0.1 microseconds to 10 milliseconds.

4. The magnetism detection device according to claim 2, further including:
a plurality of the magnetoresistive elements,
wherein the detection unit detects the external magnetic field on a basis of a difference between an integrated value of the first staying time and an integrated value of the second staying time in each of the plurality of magnetoresistive elements.

5. The magnetism detection device according to claim 2, further including:
a conversion unit that converts a charge having flowed through the magnetoresistive element into a digital value,
wherein the detection unit specifies the first staying time and the second staying time in the magnetoresistive element on a basis of the digital value.

6. The magnetism detection device according to claim 5, further including:
a low-pass filter disposed between the magnetoresistive element and the conversion unit.

7. The magnetism detection device according to claim 2, further including:
a gate circuit that opens and closes depending on a resistance value of the magnetoresistive element,
wherein the detection unit specifies the first staying time and the second staying time on a basis of a number of pulses of a pulse signal that has been conducted through the gate circuit during a period in which the gate circuit has been in an open state.

8. The magnetism detection device according to claim 2, further including:
an accumulation unit that accumulates charges having flowed through the magnetoresistive element,
wherein the detection unit specifies the first staying time and the second staying time on a basis of an amount of the charges accumulated in the accumulation unit.

9. The magnetism detection device according to claim 2,
wherein the detection unit specifies the first staying time and the second staying time on a basis of an amount of charges accumulated in the magnetoresistive element.

10. The magnetism detection device according to claim 1, further including:
an element assembly including a plurality of the magnetoresistive elements connected in parallel and/or in series,
wherein the detection unit detects an external magnetic field on a basis of a resistance value of the element assembly.

11. The magnetism detection device according to claim 10,
wherein the element assembly is integrated on a single semiconductor chip or a plurality of semiconductor chips.

12. The magnetism detection device according to claim 1, further including:
a plurality of the magnetoresistive elements arrayed in a two-dimensional lattice pattern; and
a drive circuit that drives the plurality of magnetoresistive elements row by row or column by column.

13. The magnetism detection device according to claim 1, further including:
a plurality of the magnetoresistive elements; and
a plurality of charge-coupled elements that sequentially transfers and aggregates charges having flowed through the respective magnetoresistive elements.

14. The magnetism detection device according to claim 1, further including:
a plurality of the magnetoresistive elements,
wherein each of the magnetoresistive elements has a likely axis to which the magnetization direction of the free layer is more likely to be oriented than to other directions and an unlikely axis to which the magnetization direction of the free layer is less likely to be oriented than to other directions, and
a direction of the likely axis of at least one of the plurality of magnetoresistive elements is different from a direction of the likely axis of another magnetoresistive element.

15. The magnetism detection device according to claim 14,
wherein, in at least one of the plurality of magnetoresistive elements, a length in a direction of the likely axis is longer than a length in a direction of the unlikely axis.

16. The magnetism detection device according to claim 14,
wherein a planar shape of at least one of the plurality of magnetoresistive elements is an elliptical shape.

17. The magnetism detection device according to claim 14,
wherein a planar shape of at least one of the plurality of magnetoresistive elements is circular.

18. The magnetism detection device according to claim 14,
wherein the plurality of magnetoresistive elements includes:
a first magnetoresistive element in which a direction of the likely axis is a first direction; and
a second magnetoresistive element in which a direction of the likely axis is a second direction different from the first direction by 90°.

19. The magnetism detection device according to claim 18,
wherein the plurality of magnetoresistive elements includes:
a third magnetoresistive element in which a direction of the likely axis is a third direction different from the first direction by 45° and different from the second direction by −45°; and
a fourth magnetoresistive element in which a direction of the likely axis is a fourth direction different from the first direction by 135° and different from the second direction by 45°.

20. The magnetism detection device according to claim 18,
wherein the plurality of magnetoresistive elements further includes a fifth magnetoresistive element in which a direction of the likely axis is a fifth direction different by 90° from each of the first direction and the second direction.
